(19) United States
(12) Patent Application Publication
(10) Pub. No.: US 2025/0178022 A1
(43) Pub. Date: Jun. 5, 2025

(54) SUBSTRATE PROCESSING METHOD AND SUBSTRATE PROCESSING DEVICE

(71) Applicant: SCREEN Holdings Co., Ltd., Kyoto (JP)

(72) Inventor: Atsuro EITOKU, Kyoto-shi (JP)

(21) Appl. No.: 18/933,891

(22) Filed: Oct. 31, 2024

(30) Foreign Application Priority Data
Dec. 1, 2023 (JP) 2023-203734

(51) Int. Cl. B05C 11/10; B05B 15/68; G06T 7/70; H01L 21/66

(52) U.S. Cl. CPC B05C 11/1002; B05B 15/68; G06T 7/70; G06T 2207/30148; H01L 22/26

(57) ABSTRACT

A substrate processing method includes a processing process, an imaging process, a synchronizing process, and a calculation process. In the processing process, a controller outputs a control signal to at least one driver of a processing unit while measuring a time and makes the processing unit perform processing on a substrate. In the imaging process, a camera takes an image in the chamber to generate image data. In the synchronizing process, the controller performs synchronizing processing of reducing a difference between a current time measured by the controller and a current time measured by the camera. In the calculation process, an occurrence time of an event change in the chamber is calculated based on an imaging time of the image data, and a time difference between an output time of the control signal and the occurrence time is obtained based on a synchronized time.

### BACKGROUND OF THE INVENTION

### Field of the Invention

The present disclosure relates to a substrate processing method and a substrate processing device.

### Description of the Background Art

Proposed conventionally is a substrate processing device supplying a processing solution to a substrate to perform processing on the substrate (for example, Japanese published unexamined patent application No. 2021-190511). In Japanese published unexamined patent application No. 2021-190511, the substrate processing device includes a chamber, a spin chuck, a nozzle, a supply pipe, a valve, a camera, and a controller. The spin chuck is provided in the chamber, and rotates the substrate around a vertical rotational axis line passing through a center of the substrate while holding the substrate in a horizontal posture. The nozzle is provided in the chamber, and discharges a processing solution toward an upper surface of the rotated substrate. Specifically, when the controller opens the valve, the processing solution is supplied to the nozzle through the supply pipe, and is discharged from the nozzle toward the upper surface of the substrate. The processing solution landing the upper surface of the substrate flows to an outer side in a radial direction upon receiving centrifugal force caused by the rotation of the substrate, and flies in various directions from a peripheral edge of the substrate. The processing solution acts on the upper surface of the substrate; thus, processing in accordance with the processing solution is performed on the substrate.

The camera takes an image in the chamber to generate taken image data. The controller monitors a monitoring target object in the chamber based on the taken image data.

The controller outputs a control signal to the valve, thereby being able to open the valve. The controller has a function of measuring a time, thus can grasp an output time of the control signal. In the meanwhile, the controller can detect change of a discharge state of the processing solution from the nozzle based on the taken image data and obtain a change time of the discharge state based on an imaging time of the taken image data, for example. However, when there is a time lag between a clock of the camera and a control clock of the controller, the controller cannot accurately measure the output time of the control signal and the change time of the discharge state on the same time axis. In this case, there is a possibility that the controller cannot appropriately monitor the monitoring target object.

### SUMMARY

According to one aspect, a substrate processing method includes: a processing step of outputting a control signal to at least one driver of at least one processing unit while a controller measures a time and making the processing unit perform processing on at least one substrate transported into a chamber; imaging step of making a camera take an image in the chamber and generating image data in at least a part of a period in the processing step; a synchronizing step of performing synchronizing processing of reducing a difference between a current time measured by the controller and a current time measured by the camera; and a calculation step of detecting an event change in the chamber based on the image data, calculating an occurrence time of the event change based on an imaging time of the image data, and obtaining a time difference between an output time of the control signal and the occurrence time of the event change based on a synchronized time.

According to another aspect, a substrate processing device includes: a chamber; a camera taking an image of an inner side of the chamber and generating image data; a driver for performing processing on a substrate transported into the chamber; and a controller outputting a control signal to the driver so that the driver performs processing on the substrate transported into the chamber, wherein the controller performs synchronizing processing of reducing a difference between a current time measured by the controller and a current time measured by the camera, detects an event change in the chamber based on the image data, calculates an occurrence time of the event change based on an imaging time of the image data, and obtains a time difference between an output time of the control signal and the occurrence time of the event change based on a synchronized time.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically illustrating an example of a configuration of a substrate processing device.

FIG. 2 is a block diagram schematically illustrating an example of a configuration of a controller.

FIG. 3 is a vertical cross-sectional view schematically illustrating an example of a configuration of a processing unit.

FIG. 4 is a flow chart illustrating a first example of an operation of the processing unit.

FIG. 5 is a diagram schematically illustrating an example of a timing of outputting a control signal by the controller in coating processing and a timing of an event change in a chamber 10 occurring by an operation of a driver in accordance with the control signal.

FIG. 6 is a diagram illustrating an example of temporal change of a rotational speed of a substrate W in a third process of the coating processing.

FIG. 7 is a flow chart illustrating an example of monitoring processing.

FIGS. 8A and 8B are diagrams each schematically illustrating an example of image data.

FIGS. 9A and 9B are diagrams each schematically illustrating an example of the image data.

FIG. 10 is a diagram schematically illustrating an example of the image data.

FIGS. 11A, 11B, and 11C are diagrams for explaining calculation of a time difference of occurrence times of different event changes.

FIG. 12 is a diagram schematically illustrating an example of temporal data.

FIG. 13 is a diagram schematically illustrating an example of inter-device data.

FIG. 14 is a flow chart illustrating a second example of an operation of the processing unit.

### DESCRIPTION OF THE PREFERRED EMBODIMENTS

Embodiments are described hereinafter in detail with reference to the drawings. It should be noted that dimensions of components and the number of components are illustrated in exaggeration or in simplified form, as appropriate, in the drawings for the sake of easier understanding. The same reference numerals are assigned to parts having a similar configuration and function, and the repetitive description is omitted in the description hereinafter.

In the description hereinafter, the same reference numerals will be assigned to the similar constituent elements in the drawings, and the constituent elements having the same reference numeral have the same name and function. Accordingly, the detailed description on them may be omitted to avoid a repetition in some cases.

In the following description, even when ordinal numbers such as “first” or “second” are stated, the terms are used to facilitate understanding of contents of embodiments for convenience, and therefore, the usage of the ordinal numbers does not limit the indication of the ordinal numbers to ordering.

Unless otherwise noted, the expressions indicating relative or absolute positional relationships (e.g., “in one direction”, “along one direction”, “parallel”, “orthogonal”, “central”, “concentric”, and “coaxial”) include not only those exactly indicating the positional relationships but also those where an angle or a distance is relatively changed within tolerance or to the extent that similar functions can be obtained. Unless otherwise noted, the expressions indicating equality (e.g., “same”, “equal”, and “uniform”) include not only those indicating quantitatively exact equality but also those in the presence of a difference within tolerance or to the extent that similar functions can be obtained. Unless otherwise noted, the expressions indicating shapes (e.g., “rectangular” or “cylindrical”) include not only those indicating geometrically exact shapes but also those indicating, for example, roughness or a chamfer to the extent that similar effects can be obtained. An expression “comprising”, “with”, “provided with”, “including”, or “having” a certain constituent element is not an exclusive expression for excluding the presence of the other constituent elements. An expression “at least one of A, B, and C” involves only A, only B, only C, arbitrary two of A, B, and C, and all of A, B, and C.

### <Whole Configuration of Substrate Processing Device>

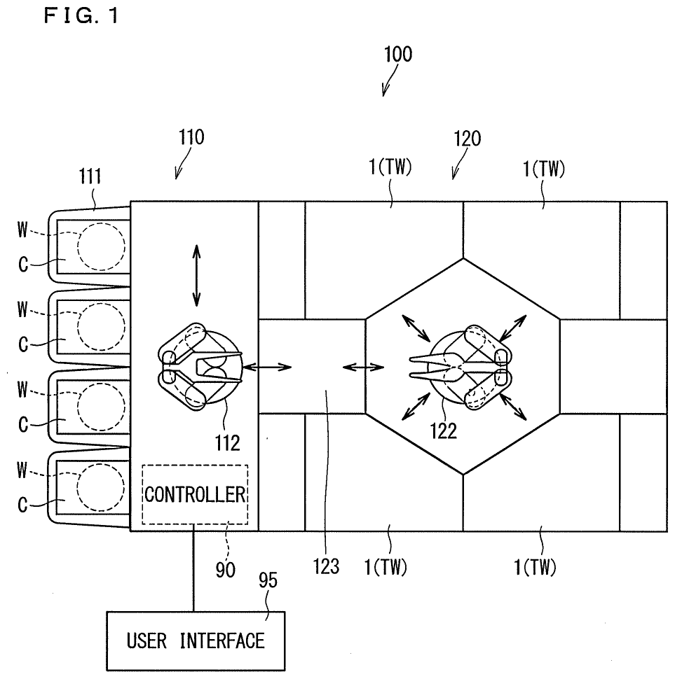

FIG. 1 is a plan view schematically illustrating an example of a configuration of a substrate processing device 100. The substrate processing device 100 is a single wafer processing device performing processing on a substrate W one by one.

The substrate W is a semiconductor wafer, a liquid crystal display apparatus substrate, an electroluminescence (EL) substrate, a flat panel display (FPD) substrate, an optical display substrate, a magnetic disk substrate, an optical disk substrate, a magnetic optical disk substrate, a photomask substrate, or a solar battery substrate, for example. The substrate W has a thin plate-like shape. In the description hereinafter, the substrate W is a semiconductor wafer. The substrate W is a disk-like shape, for example. A diameter of the substrate W is approximately 300 mm, and a film thickness of the substrate W is approximately equal to or larger than 0.5 mm and approximately equal to or smaller than 3 mm.

In the example in FIG. 1, the substrate processing device 100 includes an indexer block 110, a processing block 120, and a controller 90. The processing block 120 is a part mainly performing processing on the substrate W, and the indexer block 110 is a part mainly transporting the substrate W between an outer part of the substrate processing device 100 and the processing block 120.

The indexer block 110 includes a load port 111 and a first transportation part 112. A substrate housing container (referred to as a carrier hereinafter) C transported from an outer part is disposed on the load port 111. The plurality of substrates W are housed in the carrier C. For example, the plurality of substrates W are housed in the carrier C while being arranged at intervals in a vertical direction.

The first transportation part 112 is a transfer robot, takes out the unprocessed substrate W from the carrier C disposed on each load port 111, and transports the substrate W to the processing block 120. The first transportation part 112 can also be referred to as an indexer robot. The processing block 120 performs processing on the substrate W. The first transportation part 112 receives the substrate W which has been processed from the processing block 120, and transports the substrate W to the carrier C of the load port 111.

In the example in FIG. 1, the processing block 120 includes a plurality of processing units 1 and a second transport part 122. The second transport part 122 is a transport robot, and transports the substrate W between the first transportation part 112 and the plurality of processing units 1. The second transport part 122 receives the unprocessed substrate W from the first transportation part 112 via a mounting part 123, and transports the substrate W to the processing unit 1, for example. The processing unit 1 performs processing on the substrate W. A configuration of the processing unit 1 is described hereinafter. The second transport part 122 takes out the substrate W which has been processed from the processing unit 1, and transports the substrate W to the first transportation part 112 via the mounting part 123, for example.

The second transport part 122 may transport the substrate W between the plurality of processing units 1 as necessary. For example, it is applicable that the second transport part 122 transports the substrate W processed by the processing unit 1 to the other processing unit 1, and transports the substrate W processed by the other processing unit 1 to the first transportation part 112.

In the example in FIG. 1, the plurality of processing units 1 are provided to surround the second transport part 122 in a plan view. This second transportation part 122 can also be referred to as a center robot. In the example in FIG. 1, four processing units 1 surround the second transport part 122. The plurality of processing units 1 may be stacked in a vertical direction in each position where each processing unit 1 is provided in a plan view. That is to say, a plurality of (four in FIG. 1) towers TW made up of the plurality of processing units 1 stacked in the vertical direction may be provided to surround the second transport part 122 in a plan view.

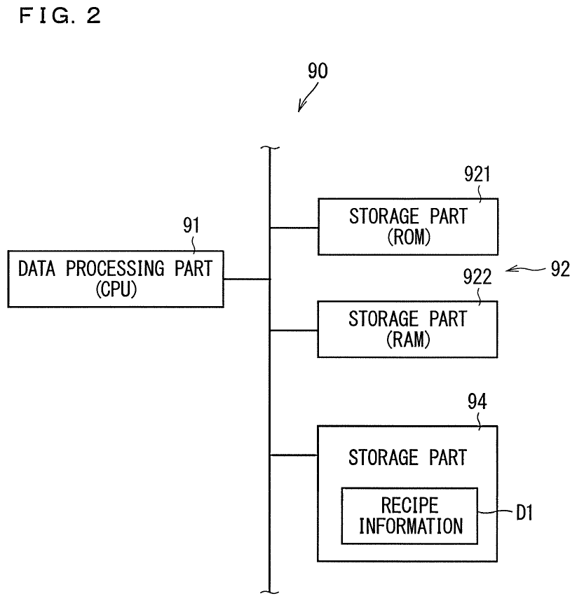

The controller 90 collectively controls the substrate processing device 100. Specifically, the controller 90 controls the first transportation part 112, the second transport part 122, and the processing unit 1. FIG. 2 is a block diagram schematically illustrating an example of a configuration of the controller 90. The controller 90 is an electrical circuit, and includes a data processing part 91 and a storage part 92, for example. The data processing part 91 may be an arithmetic processing unit such as a central processor unit (CPU), for example. The storage part 92 may include a non-transitory storage part (for example, a read only memory (ROM)) 921 and a transitory storage part (for example, a random access memory (RAM)) 922. The non-transitory storage part 921 may store a program regulating processing executed by the controller 90, for example. When the data processing part 91 executes this program, the controller 90 can execute processing regulated by the program. Needless to say, hardware such as a dedicated logic circuit may execute a part of or whole processing executed by the controller 90.

In the example in FIG. 2, a storage part 94 is connected to the controller 90. The storage part 94 is a hard disk or a non-transitory memory, for example. In the example in FIG. 2, the storage part 94 stores recipe information D1. The recipe information D1 is described hereinafter.

The controller 90 also has a function of measuring a time. The controller 90 includes a clock generator (a clock generation circuit: not shown) generating a control clock, and measures a time based on the control clock, for example.

In the example in FIG. 1, a user interface 95 is connected to the controller 90. The user interface 95 includes an input device and a notification part. The input device is a device receiving a user input, and is an input device such as a mouse and a keyboard, for example. The notification part is a device transmitting information to a user, and includes at least one of a display such as a liquid crystal display and a sound output part such as a speaker, for example.

### <Outline of Processing Unit>

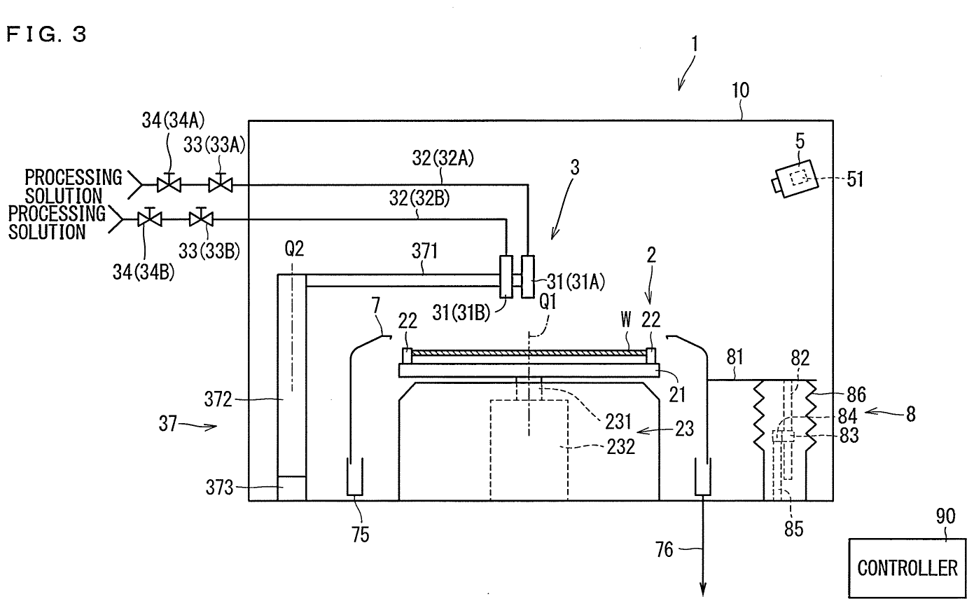

FIG. 3 is a vertical cross-sectional view schematically illustrating an example of a configuration of the processing unit 1. All of the processing units 1 belonging to the substrate processing device 100 need not have a configuration exemplified in FIG. 3. It is sufficient that at least one processing unit 1 has the configuration exemplified in FIG. 3. The processing unit 1 includes a chamber 10, various types of drivers for performing processing on the substrate W, and a camera 5. As described in detail hereinafter, the controller 90 outputs a control signal to each driver of the processing unit 1, and each driver are appropriately operated in response to the control signal; thus, the processing unit 1 can appropriately perform processing on the substrate W. In the present embodiment, as described in detail hereinafter, the controller 90 monitors an inner side of the chamber 10 based on image data of an image taken by the camera 5. Each driver is described hereinafter while a configuration of the processing unit 1 is firstly described.

The chamber 10 includes an inner space. The inner space corresponds to a processing space for performing processing on the substrate W. An openable and closable transfer port (not shown) is provided to the chamber 10. The second transport part 122 transports the unprocessed substrate W into the chamber 10 through the transfer port, and transports the substrate W which has been processed from the chamber 10 through the transfer port.

In the example in FIG. 3, the processing unit 1 further includes a substrate holding part 2, a discharge part 3, a guard 7, and a guard lifting driver 8. The substrate holding part 2 is provided in the chamber 10, and rotates the substrate W around a rotation axis line Q1 while holding the substrate W in a horizontal posture. The horizontal posture herein indicates a posture in which a thickness direction of the substrate W follows the vertical direction. The rotation axis line Q1 is an axis extending along the vertical direction through a center of the substrate W. Such a substrate holding part 2 can also be referred to as a spin chuck.

In the example in FIG. 3, the substrate holding part 2 includes a spin base 21, a chuck pin 22, and a rotation driver 23. The spin base 21 has a plate-like shape (for example, a disk-like shape), and is provided so that a thickness direction thereof follows the vertical direction. The plurality of chuck pins 22 are provided to an upper surface of the spin base 21. The plurality of chuck pins 22 are provided at regular intervals along a circumferential direction of the rotation axis line Q1. The plurality of chuck pins 22 are provided to be able to be displaced between a holding position and a release position described next. The holding position is a position where the chuck pin 22 has direct contact with a peripheral edge of the substrate W. When the plurality of chuck pins 22 stops at respective holding positions, the plurality of chuck pins 22 hold the substrate W. FIG. 3 illustrates the chuck pins 22 stopping at the holding positions. The release position is a position where each chuck pin 22 is away from the substrate W. When the plurality of chuck pins 22 stops at respective release positions, holding of the substrate W by the plurality of chuck pins 22 is released. The substrate holding part 2 also includes a pin driver (not shown) displacing the chuck pin 22. The pin driver includes a drive source such as a motor or an air cylinder, for example, and is controlled by the controller 90.

The rotation driver 23 includes a shaft 231 and a motor 232. An upper end of the shaft 231 is connected to a lower surface of the spin base 21, and the shaft 231 extends along the rotation axis line Q1 from the lower surface of the spin base 21. The motor 232 is controlled by the controller 90, and rotates the shaft 231 around the rotation axis line Q1. Accordingly, the spin base 21, the chuck pin 22, and the substrate W are integrally rotated around the rotation axis line Q1. This rotation driver 23 corresponds to an example of a driver for performing processing on the substrate W.

The substrate holding part 2 needs not necessarily include the chuck pin 22. For example, the substrate holding part 2 may hold the substrate W by a chuck system such as vacuum chuck, electrostatic chuck, and Bernoulli chuck.

The discharge part 3 discharges a processing fluid toward a main surface of the substrate W held by the substrate holding part 2. The processing fluid is gas or a fluid (referred to as a processing solution hereinafter), for example, and is a processing solution as a specific example. In the example in FIG. 3, the discharge part 3 includes a nozzle 31, a supply pipe 32, a supply valve 33, and a flow amount adjustment valve 34. The nozzle 31 is provided in the chamber 10. In the example in FIG. 3, the nozzle 31 is located on a vertically upper side with respect to the substrate W held by the substrate holding part 2 and discharges the processing solution toward an upper surface of the substrate W. The nozzle 31 may be a nozzle discharging a processing solution in a continuous flow state, or may also be a mist nozzle or a spray nozzle discharging a processing solution in a liquid drop state. Herein, as an example, the nozzle 31 is a nozzle discharging a processing solution in a continuous flow state.

The processing solution may be a coating solution, a chemical solution, a rinse solution, or a neutralization solution. The coating solution is a solvent containing a component of a thin film formed on the main surface of the substrate W. The coating solution may be a resist solution. The chemical solution may be a cleaning solution removing a foreign object on the main surface of the substrate W, or may also be an etching solution removing a target film. Applicable as the chemical solution, for example, is a liquid of nitric hydrofluoric acid obtained by mixing hydrofluoric acid, nitric acid, and water, a hydrofluoric acid-hydrogen peroxide solution (FPM) obtained by mixing hydrofluoric acid, hydrogen peroxide, and water, tetramethylammonium hydroxide (TMAH), a mixed solution of sulfuric acid and hydrogen peroxide water (SPM), ammonia water, and a mixed solution of ammonia, hydrogen peroxide, and water (SC-1). It is also applicable that the chemical solution is not a mixed solution but is a single solution. For example, a single solution of hydrofluoric acid (HF), hydrogen peroxide water, or sulfuric acid can be applied as the chemical solution. The rinse solution may be pure water (that is to say, deionization water), or may also be an organic solvent having higher volatileness than the pure water, such as isopropyl alcohol. The neutralization solution is a liquid for removing a charge of the substrate W, and may be carbon dioxide water. Carbon dioxide water may also be used as a rinse solution.

In the example in FIG. 3, a downstream end of the supply pipe 32 is connected to the nozzle 31. An upstream end of the supply pipe 32 is connected to a processing solution supply source. The processing solution supply source includes a tank (not shown) retaining the processing solution, and supplies the processing solution to the upstream end of the supply pipe 32. In the example in FIG. 3, the supply valve 33 and the flow amount adjustment valve 34 are provided to the supply pipe 32. The supply valve 33 switches opening and closing of the supply pipe 32, and the flow amount adjustment valve 34 adjusts a flow amount of the processing solution flowing in the supply pipe 32. The flow amount adjustment valve 34 may be a mass flow controller. The controller 90 controls these valves. Each of the supply valve 33 and the flow amount adjustment valve 34 corresponds to an example of a driver for performing processing on the substrate W.

The processing unit 1 may include the plurality of nozzles 31 corresponding to plural types of processing solutions, respectively. In the example in FIG. 3, a nozzle 31A and a nozzle 31B are illustrated as the nozzle 31. The nozzle 31A is a nozzle for an coating solution, for example, and the nozzle 31B is a nozzle for pure water, for example. In the description hereinafter, “A” may be added to an end of a reference numeral of each of the supply pipe 32, the supply valve 33, and the flow amount adjustment valve 34 corresponding to the nozzle 31A, and “B” may be added to an end of a reference numeral of each of the supply pipe 32, the supply valve 33, and the flow amount adjustment valve 34 corresponding to the nozzle 31B.

In the example in FIG. 3, the processing unit 1 includes a nozzle movement driver 37 moving the nozzle 31. When the plurality of nozzles 31 are provided, the nozzle movement driver 37 may integrally move the plurality of nozzles 31. For example, it is also applicable that the plurality of nozzles 31 are coupled side by side to constitute a nozzle head, and the nozzle movement driver 37 moves the nozzle head. The nozzle movement driver 37 moves the nozzle 31 between a nozzle processing position and a nozzle standby position described hereinafter. The nozzle processing position is a position where the nozzle 31 discharges the processing solution toward the main surface of the substrate W held by the substrate holding part 2, and is a position facing a center part of the substrate W in the vertical direction, for example. In the example in FIG. 3, the nozzle 31 located in the nozzle processing position is illustrated. The nozzle standby position is a position where the nozzle 31 does not discharge the processing solution toward the main surface of the substrate W, and is a position on an outer side of the substrate W in a radial direction.

In the example in FIG. 3, the nozzle movement driver 37 includes an arm 371, a support column 372, and a drive source 373. The support column 372 is provided on an outer side of the guard 7 described hereinafter in a radial direction, and extends along the vertical direction. The arm 371 extends along a horizontal direction, a tip end thereof is connected to the nozzle 31 (or the nozzle head), and a base end thereof is connected to the support column 372. The drive source 373 is controlled by the controller 90, and rotates the support column 372 in a forward-reverse direction around a center axis line Q2 within a predetermined angular range. The drive source 373 includes a motor, for example. When the support column 372 is rotated in the forward-reverse direction around the center axis line Q2 in the predetermined angular range, the nozzle 31 reciprocates along a circumferential direction of the center axis line Q2. The support column 372 is disposed so that the nozzle processing position and the nozzle standby position are located on a movement trajectory of the nozzle 31. The nozzle movement driver 37 needs not necessarily have the configuration in FIG. 3, but may include a linear motion mechanism such as a linear motor, for example. The nozzle movement driver 37 corresponds to an example of a driver for performing processing on the substrate W.

When the nozzle 31 discharges the processing solution toward the main surface of the rotated substrate W while being located in the nozzle processing position, the processing solution lands the main surface of the substrate W. The processing solution flows to the outer side in the radial direction upon receiving centrifugal force caused by the rotation of the substrate W, and flies in various directions in an outer side of the peripheral edge of the substrate W. Accordingly, processing corresponding to a type of the processing solution are performed on the substrate W.

The guard 7 receives the processing solution flying from the peripheral edge of the substrate W. The guard 7 has a tubular shape surrounding the substrate W held by the substrate holding part 2.

The guard lifting driver 8 is controlled by the controller 90, and lifts up and down the guard 7. The guard lifting driver 8 lefts up and down the guard 7 between a guard processing position and a guard standby position described hereinafter. The guard processing position is a position where an upper end of the guard 7 is located on a vertically upper side of the upper surface of the substrate W. The processing solution flying from the peripheral edge of the substrate W is received by an inner peripheral surface of the guard 7 in a state where the guard 7 is located in the guard processing position. The guard standby position is a position where the upper end of the guard 7 is located on a vertically lower side of the upper surface of the spin base 21. In a state where the guard 7 is located in the guard standby position, collision of the second transport part 122 and each substrate W with the guard 7 can be prevented when the substrate W is transported.

In the example in FIG. 3, the guard lifting driver 8 has a so-called rack-and-pinion mechanism. Specifically, the guard lifting driver 8 includes a support plate 81, a rack 82, a gear 83, a motor 84, a fixing member 85, and a bellows 86. The support plate 81 extends in an outer side in a radial direction from a tubular part 71 of the guard 7, for example. The support plate 81 has a plate-like shape, and is provided so that a thickness direction thereof follows the vertical direction. The rack 82 has a rod-like shape extending along the vertical direction, and a plurality of gears are provided to a side surface thereof. The gear 83 is an external gear, and meshes with the rack 82. The motor 84 is connected to gear 83. The fixing member 85 fixes the motor 84 to the chamber 10. The motor 84 is controlled by the controller 90, and rotates the gear 83 in a forward-reverse direction. The rack 82, the support plate 81, and the guard 7 are integrally lifted up and down by the rotation of this gear 83. The bellows 86 connects a lower surface of the support plate 81 and a floor surface of the chamber 10, and houses the rack 82, the gear 83, the motor 84, and the fixing member 85. The bellows 86 can extend and shrink in the vertical direction. The guard lifting driver 8 is not limited to the rack-and-pinion mechanism; however, also applicable is a ball screw mechanism or a direct acting mechanism with a linear motor, for example. The guard lifting driver 8 corresponds to an example of a driver for performing processing on the substrate W. The plurality of guards 7 corresponding to plural types of processing solutions, respectively, may be provided in the processing unit 1.

In the example in FIG. 3, a cup 75 corresponding to the guard 7 is provided. The cup 75 includes an annular (toric, for example) concave part (groove) surrounding the rotation axis line Q1. The cup 75 receives the processing solution flowing down the inner peripheral surface of the corresponding guard 7. An upstream end of a discharge pipe 76 is connected to a bottom part, for example, of the cup 75. The processing solution received by each cup 75 is discharged outside the processing unit 1 through the discharge pipe 76.

In the example in FIG. 3, the camera 5 is provided in the chamber 10. The camera 5 is fixed to the chamber 10 by a fixing member not shown in the diagrams, for example. The camera 5 includes a solid-state imaging element such as a charge coupled device (CCD) or a complementary metal oxide semiconductor (CMOS), an optical system such as a lens, and a camera controller 51, for example. The camera controller 51 generates image data upon receiving a signal from the solid-state imaging element. The camera 5 outputs the image data to the controller 90. The image data may be a frame of dynamic picture image data. The camera controller 51 also has a function of measuring a time. For example, the camera controller 51 includes a clock generator (a clock generation circuit) not shown in the diagrams, and measures a time based on a camera clock outputted from the clock generator. The camera 5 can generate image data (each frame) for each imaging time. A hardware configuration of the camera controller 51 may be similar to the controller 90, for example.

The camera 5 is provided in a position where an imaging region includes a monitoring target object in the chamber 10. In the example in FIG. 3, the camera 5 is provided to a position on a vertically upper side of the substrate W held by the substrate holding part 2 and an outer side of the substrate W in the radial direction. As illustrated in FIG. 3, the camera 5 may also be provided to an outer side of the guard 7 in the radial direction. In the example in FIG. 3, the camera 5 takes an image of the imaging region from an obliquely upper side. In other words, the camera 5 takes an image of the imaging region along an obliquely lower side.

The camera 5 outputs the image data to the controller 90. The controller 90 can also function as an image processing part performing processing on the image data. The controller 90 detects an event change in the chamber 10 based on the image data as described hereinafter.

### <First Example of Substrate Processing (Processing Step)>

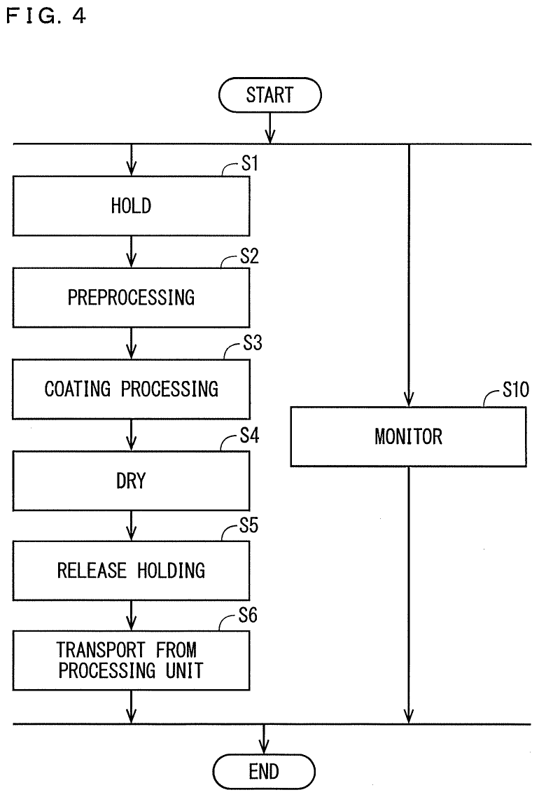

Described next is a first example of substrate processing by the processing unit 1. Herein, the processing unit 1 forms a coating film on the main surface (specifically, the upper surface) of the substrate W. FIG. 4 is a flow chart illustrating a first example of an operation of the processing unit 1. Step S1 to Step S6 illustrate an example of substrate processing (corresponding to an example of processing step) on the substrate W, and Step S10 illustrates monitoring processing of monitoring an operation of various types of drivers of the processing unit 1. The monitoring processing is described hereinafter.

The substrate processing on this substrate W can be achieved when the controller 90 controls the substrate processing device 100 based on the recipe information D1. The recipe information D1 is information indicating procedure of the processing on the substrate W, and is stored in the storage part 94, for example. In this substrate processing, the controller 90 outputs a control signal to a driver of the processing unit 1 based on the recipe information D1 and a time while measuring the time, thereby making the processing unit 1 perform the processing on the substrate W transported into the chamber 10.

In the example in FIG. 4, the substrate W is transported from the second transport part 122 to the processing unit 1, and the substrate holding part 2 holds the substrate W (Step S1). For example, after the second transport part 122 passes the substrate W to the substrate holding part 2, the controller 90 outputs the control signal for displacing the chuck pin 22 to the holding position to the substrate holding part 2 (specifically, the pin driver). The substrate holding part 2 displaces the chuck pin 22 from the release position to the holding position in response to the control signal. Accordingly, the substrate holding part 2 holds the substrate W.

Next, the processing unit 1 performs preprocessing on the substrate W (Step S2). Processing of washing the substrate W can be applied to the preprocessing, for example. Step S2 needs not necessarily be performed.

Herein, in the preprocessing, the processing unit 1 supplies various processing solutions to the main surface of the substrate W while rotating the substrate W. For example, the processing unit 1 supplies pure water to the main surface of the substrate W. More specifically, the controller 90 firstly outputs lift-up instruction as the control signal to the guard lifting driver 8. The guard lifting driver 8 lifts up the guard 7 to the guard processing position in response to the lift-up instruction. The controller 90 outputs rotation instruction as the control signal to the substrate holding part 2 (specifically, the rotation driver 23). The substrate holding part 2 starts rotating the substrate W in response to the rotation instruction.

The controller 90 outputs movement instruction as the control signal to the nozzle movement driver 37. The movement instruction in the preprocessing is a control signal for moving the nozzle 31B to the nozzle processing position. The nozzle movement driver 37 moves the nozzle 31B to the nozzle processing position in response to the movement instruction. As a specific example, the nozzle movement driver 37 moves the nozzle 31B to a position where the nozzle 31B faces the center of the substrate W in the vertical direction.

Next, the controller 90 outputs open instruction as the control signal to the supply valve 33B. The supply valve 33B opens the supply pipe 32B in response to the open instruction. Accordingly, the pure water is discharged from a discharge port of the nozzle 31B toward the main surface of the substrate W. The pure water landing the center part of the substrate W flows to the outer side in the radial direction upon receiving centrifugal force caused by the rotation of the substrate W, and flies in various directions from the peripheral edge of the substrate W. Accordingly, the main surface of the substrate W is washed. Then, when a predetermined time regulated in the recipe information D1 elapses, the controller 90 outputs close instruction as the control signal to the supply valve 33B. The supply valve 33B closes the supply pipe 32B in response to the close instruction. Accordingly, discharge of the pure water from the nozzle 31B is stopped.

Next, the processing unit 1 performs coating processing on the substrate W (Step S3). More specifically, the processing unit 1 discharges the coating solution from the nozzle 31A toward the main surface of the substrate W while rotating the substrate W. Herein, a first process to third process are regulated as processes falling under the coating processing in the recipe information D1.

TABLE 1
Recipe information

| Process | Required time | Operation content |
|---|---|---|
| . | . | . |
| . | . | . |
| . | . | . |
| First process | 1 second | Move nozzle |
| | | Start discharging coating solution |
| Second process | 1.8 seconds | Continuously discharge coating solution |
| | | Change rotational speed |
| Third process | 4.0 seconds | Change rotational speed |
| | | Stop discharging coating solution |
| . | . | . |
| . | . | . |
| . | . | . |

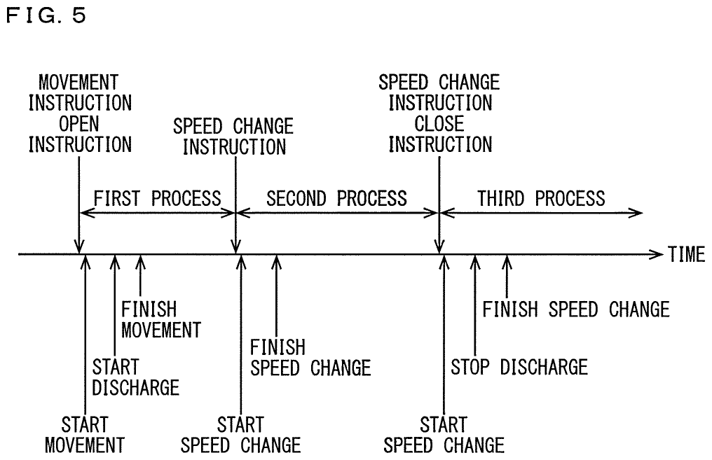

FIG. 5 is a diagram schematically illustrating an example of a timing of outputting the control signal by the controller 90 in the coating processing and a timing of an event change in a chamber 10 occurring by an operation of a driver in accordance with the control signal.

A first process is a process of starting discharging the coating solution while moving the nozzle 31A to a center position. The center position herein is an example of the nozzle processing position, and is a position facing the center of the substrate W in the vertical direction. In the first process, the controller 90 outputs the movement instruction to the nozzle movement driver 37, and outputs the open instruction to the supply valve 33A. The movement instruction in the first preprocess is a control signal for moving the nozzle 31A to the center position. The nozzle movement driver 37 moves the nozzle 31A to the center position in response to the movement instruction. The supply valve 33A opens the supply pipe 32A in response to the open instruction. In the example in FIG. 5, the movement instruction and the open instruction are outputted almost at the same time, the coating solution starts to be discharged after the nozzle 31A starts to be moved, and then the movement of the nozzle 31A is finished. A first required time of the first process is previously set to a time sufficient to complete the movement of the nozzle 31A to the center position and the operation of opening the supply valve 33A, and can be set to approximately 1 second as a specific example.

The controller 90 executes the second process in response to the elapse of the first required time from the start of the first process. The second process is a process of changing a rotational speed of the substrate W while continuously discharging the coating solution. Herein, it is assumed that the supply valve 33A keeps opening the supply pipe 32A unless the supply valve 33A receives the close instruction. The controller 90 outputs speed change instruction as the control signal to the substrate holding part 2 (specifically, the rotation driver 23) in the second process. The speed change instruction in the second process is the control signal for changing the rotational speed of the substrate W from a first speed value to a second speed value. The substrate holding part 2 changes the rotational speed of the substrate W from the first speed value to the second speed value in response to the speed change instruction. In the example in FIG. 5, the rotational speed of the substrate W starts to be changed after the speed change instruction is outputted, and then, change of the rotational speed of the substrate W is substantially finished. A second required time of the second process is previously set to a time sufficient to complete change of the rotational speed of the substrate W, and can be set to approximately 1.8 seconds as a specific example. When the rotational speed of the substrate W reaches the second speed value halfway through the second process, the rotational speed of the substrate W is ideally constant to have the second speed value.

The controller 90 executes the third process in response to the elapse of the second required time from the start of the second process. The third process is a process of stopping discharge of the coating solution while the rotational speed of the substrate W is changed. The controller 90 outputs the close instruction to the supply valve 33A while outputting the speed change instruction to the substrate holding part 2. The speed change instruction in the third process is the control signal for changing the rotational speed from the second speed value to a third speed value. The substrate holding part 2 changes the rotational speed of the substrate W from the second speed value to the third speed value in response to the speed change instruction. The third speed value can be set to be larger than the second speed value, for example. The supply valve 33A closes the supply pipe 32A in response to the close instruction. Accordingly, discharge of the coating solution from a discharge port of the nozzle 31A is stopped. In the example in FIG. 5, the speed change instruction and the close instruction are outputted almost at the same time, and discharge of the coating solution is stopped after the rotational speed of the substrate W starts to be changed, and then, change of the rotational speed of the substrate W is substantially finished. That is to say, discharge of the coating solution is stopped during change of the rotational speed of the substrate W. A third required time of the third process is previously set to a time sufficient to complete change of the rotational speed of the substrate W and discharge stop of the coating solution, for example, and can be set to approximately 4 seconds as a specific example.

According the coating processing described above, a liquid film of the coating solution is formed on the main surface of the substrate W. It is applicable that after the coating processing is finished, the controller 90 outputs the control signal to the substrate holding part 2 to stop the rotation of the substrate W, outputs lift-down instruction to the guard lifting driver 8 to lift down the guard 7 to the guard standby position, or outputs the movement instruction to the nozzle movement driver 37 to move the nozzle 31 to the nozzle standby position.

Next, the processing unit 1 dries the liquid film of the coating solution on the main surface of the substrate W to form a coating film on the main surface of the substrate W (Step S4). For example, the processing unit 1 may include a heater not shown in the diagrams. The heater is provided between the substrate W and the spin base 21 to heat the substrate W, for example. The heater may be an electric-resistive heater, or may also be an optical heater emitting light for heating (for example, infrared light). When heater heats the substrate W, the liquid film of the coating solution of the substrate W can be dried. When the processing unit 1 completes drying of the substrate W, the operation of the heater is stopped.

Next, the substrate holding part 2 releases holding of the substrate W (Step S5). For example, the controller 90 outputs holding release instruction as the control signal to the substrate holding part 2. The substrate holding part 2 moves the chuck pin 22 from the holding position to the release position in response to the holding release instruction. Next, the second transport part 122 transports the substrate W which has been processed from the processing unit 1 (Step S6).

As described above, various types of drivers of the processing unit 1 are appropriately operated; thus, the processing can be appropriately performed on the main surface of the substrate W.

A time difference occurs between a time when the controller 90 outputs the control signal to the each of various types of drivers of the processing unit 1 and a time when an event in the chamber 10 changes by the operation of the driver in response to the control signal. The time difference is also referred to as a delay time. Table 2 is a table indicating examples of a type of the driver, a type of the control signal, and a type of the event change.

TABLE 2

| Driver | Control signal | Event change in chamber |
|---|---|---|
| Supply valve | Open instruction | Change of discharge state of |
| | Close instruction | processing solution (start |
| | | discharging to/from stop |
| | | discharging) |
| Nozzle movement | Movement | Positional change of nozzle |
| driver | instruction | |
| Substrate holding | Speed change | Change of rotational speed of |
| part | instruction | substrate |

For example, the delay time occurs from a time when the controller 90 outputs the control signal to the supply valve 33 until a time when the discharge state of the nozzle 31 is changed. More specifically, the delay time occurs from a time when the controller 90 outputs the open instruction until the nozzle 31 starts discharging the processing solution. The delay time occurs from a time when the controller 90 outputs the close instruction until a time when discharge of the processing solution from the nozzle 31 is stopped. One of the reasons for these delay times is that it takes time to complete the open and close operation of the supply valve 33. Thus, these delay times are relatively long.

A delay time may occur from a time when the controller 90 outputs the movement instruction to the nozzle movement driver 37 until a time when the position of the nozzle 31 changes. However, the nozzle movement driver 37 includes the motor as the drive source, and the nozzle 31 moves with high responsibility with respect to the operation of the motor; thus, the delay time from output of the movement instruction until start of movement of the nozzle 31 is shorter than the operation of the supply valve 33. A delay time may occur from a time when the controller 90 outputs the speed change instruction to the substrate holding part 2 until a time when the rotational speed of the substrate W changes. In the similar manner, the delay time from output of the speed change instruction until start of change of the rotational speed of the substrate W is smaller than the delay time for change of the discharge state of the processing solution.

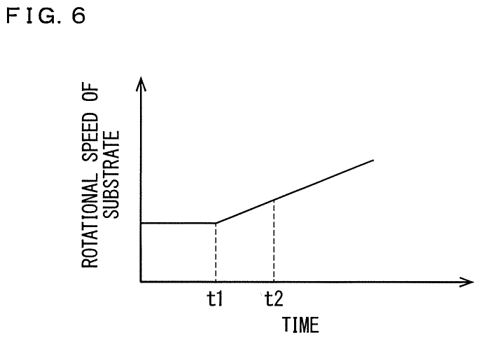

Such various types of delay times can be different for each processing unit 1 by various causes such as a variation of a load of each driver, a manufacture tolerance of each driver, and a temporal degradation, for example. Such various types of delay times are different from an assumed time (for example, a design value), there is a possibility that a degree of processing on the substrate W is not as expected. For example, there is a possibility that a film thickness of the liquid film of the coating solution on the main surface of the substrate W is deviated from an assumed film thickness. As a specific example, a time difference between a discharge stop time of the coating solution in the third process of the coating processing and a change time of the rotational speed of the substrate W has influence on the film thickness of the liquid film. FIG. 6 is a diagram illustrating an example of temporal change of the rotational speed of the substrate W in the third process of the coating processing. In the example in FIG. 6, discharge of the coating solution is stopped during increase of the rotational speed of the substrate W. When this discharge stop time t2 is deviated from the assumed time or a change start time t1 of the rotational speed is deviated from the assumed time, a value of the rotational speed of the substrate W at a discharge stop time t2 changes. Thus, the film thickness of the liquid film fluctuates in accordance with the deviation.

A time difference between a discharge start time of the coating solution in the first process of the coating processing and a change time of the rotational speed of the substrate W in the second process of the coating processing may also have influence on the film thickness of the liquid film. Thus, when the discharge start time in the first process is deviated or the change time of the rotational speed in the second process is deviated, the film thickness of the liquid film may also be deviated from the assumed film thickness. Moreover, a time difference between the movement time of the nozzle 31A in the first process and the discharge start time may also have influence on the processing. Thus, when the movement time in the first process is deviated and the discharge start time is deviated, excess or deficiency may occur in the processing.

Thus, in the present embodiment, the controller 90 calculates a time difference (a delay time) between output of the control signal to each driver of the processing unit 1 and an event change in the chamber 10 in accordance with the operation of the driver. The controller 90 outputs the control signal to each driver based on the required time in each process regulated in the recipe information D1, thus grasps an output time of the control signal. This output time is measured based on a control clock of the controller 90. In the meanwhile, the event change in the chamber 10 may be detected based on image data generated by the camera 5 as described in detail hereinafter. Since the camera 5 grasps an imaging time of the image data, the controller 90 can grasp an occurrence time of the event change based on the imaging time of the image data. However, the imaging time is measured based on a camera clock of the camera 5. In this manner, since the output time of the control signal and the imaging time of the image data are measured by the different clocks, deviation on a time axis may occur. Thus, the controller 90 synchronizes a current time measured based on the control clock with a current time measured based on the camera clock.

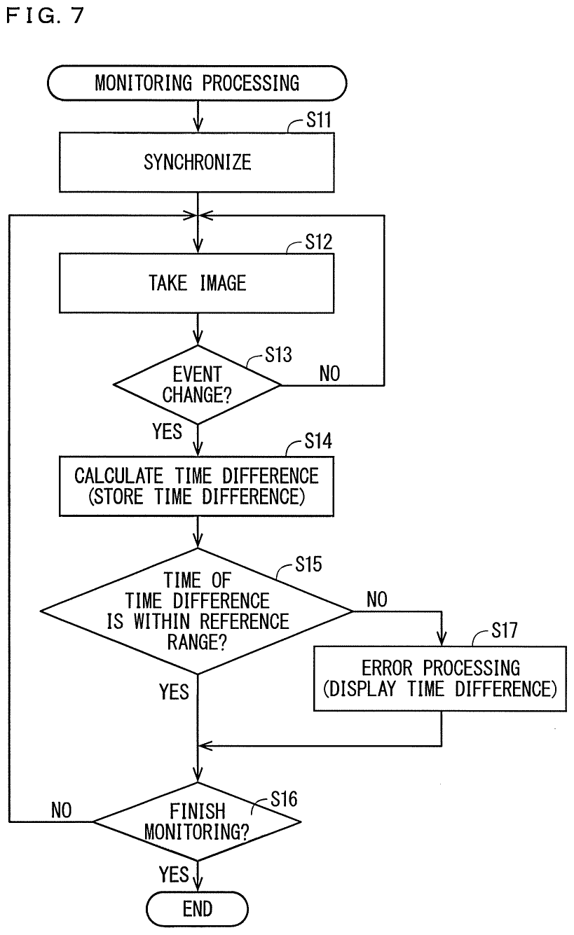

FIG. 7 is a flow chart illustrating an example of monitoring processing. A flow in FIG. 7 corresponds to an example of Step S10 in FIG. 4. In the example in FIG. 7, the controller 90 firstly performs synchronizing processing of reducing a difference between the current time measured by the controller 90 and the current time measured by the camera 5 (Step S11: synchronizing step). For example, the controller 90 may output a reset signal to the camera 5. The reset signal is a signal for initializing a time, for example, and includes information of the current time measured by the controller 90. A camera control part 51 sets the current time measured based on the camera clock to the current time measured by the controller 90 in response to the reset signal. Accordingly, the difference between the current time measured by the control clock and the current time measured by the camera clock can be reduced, and the current times can be substantially made to coincide with each other. Subsequent to this synchronizing processing, the controller 90 and the camera controller 51 can measure the time on subsequently the same time axis. The step S11 may be executed before Step S1.

Next, the processing unit 1 repetitively executes a group of Step S12 to Step S15 described hereinafter until the substrate processing is finished, for example. Thus, the sequential processing from Step S12 to Step S15 is repetitively executed in parallel to the substrate processing (Step S1 to Step S6).

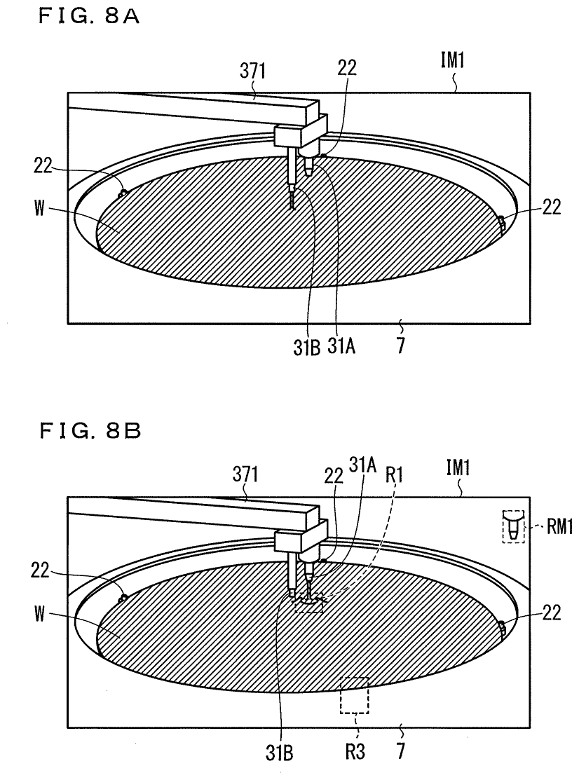

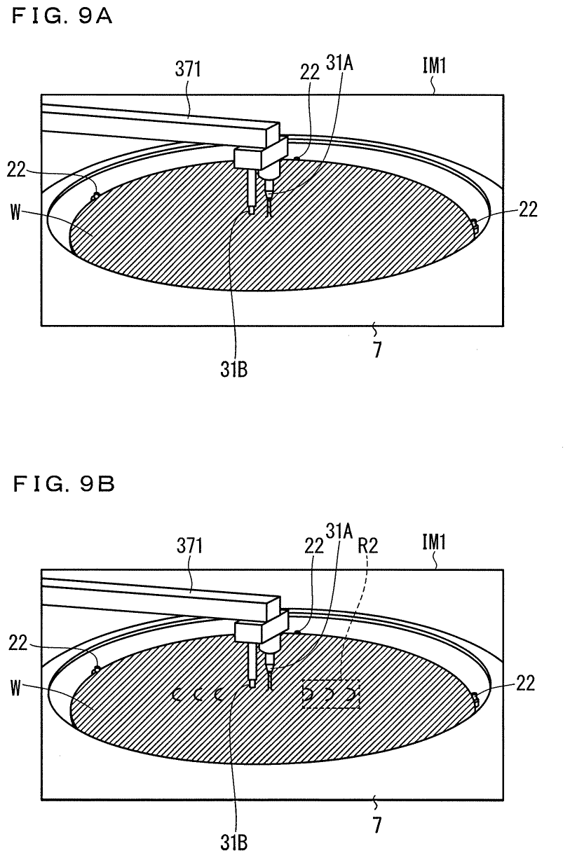

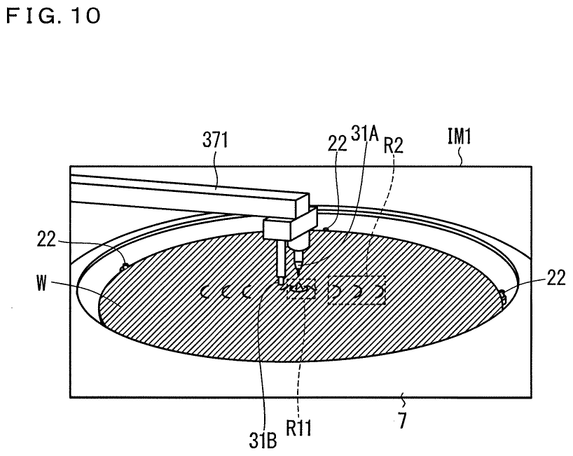

In Step S12 (imaging step), the camera 5 takes an image of the imaging region to generate image data IM1. The image data IM1 includes a frame of dynamic picture image data. Since Step S12 is repetitively performed in parallel to the substrate processing as described above, each image data IM1 includes a state in the chamber 10 corresponding to a degree of progress of the substrate processing. FIG. 8A to FIG. 10 are diagrams schematically illustrating an example of the image data IM1. The image data IM1 in each of FIG. 8A, FIG. 8B, FIG. 9A, FIG. 9B, and FIG. 10 is image data of an image taken at a timing different from each other.

In the example in FIG. 8A to FIG. 10, the image data IM1 includes a whole upper side opening of the guard 7 located in the guard processing position. In other words, the camera 5 is provided to a position where the whole upper side opening of the guard 7 is included in the imaging region. In the example in FIG. 3, since the camera 5 is provided to an outer side of the guard 7 in the radial direction and a vertically upper side of the guard 7, an imaging direction of the camera 5 is an obliquely lower side. Thus, the upper side opening of the guard 7 having a circular shape in a plan view is illustrated in an oval shape in the image data IM1.

FIG. 8A illustrates the image data IM1 of the image taken immediately before the coating processing in Step S3, FIG. 8A and FIG. 9A illustrate the image data IM1 of the image taken in the first process of the coating processing, FIG. 9B illustrates the image data IM1 of the image taken in the second processing in the coating processing, and FIG. 10 illustrates the image data IM1 of the image taken in the third process in the coating processing.

Next, in Step S13 (an event change determination step), the controller 90 determines whether or not an event change occurs in the chamber 10 based on the image data IM1. Herein, the event change as a determination target changes in accordance with a degree of progress of the substrate processing. Described hereinafter is an example of the coating processing in Step S3.

For example, in the first process of the coating processing, the controller 90 outputs the open instruction to the supply valve 33A while outputting the movement instruction to the nozzle movement driver 37. Thus, in the first process, the controller 90 determines whether or not the nozzle 31A is moved and whether or not the nozzle 31A starts discharging the coating solution based on the image data IM1 (Step S13). For example, in FIG. 8B, the nozzle 31A has not reached the center position; however, the coating solution is discharged from the discharged port of the nozzle 31A. Described hereinafter is an example of a method of determining whether or not the nozzle 31A is moved firstly, and an example of a method of determining whether or not the nozzle 31A starts discharging the coating solution next.

Firstly, the controller 90 specifies the position of the nozzle 31A in the image data IM1. For example, the controller 90 may specify the position of the nozzle 31A by a template matching using preset reference image data RM1 of the nozzle 31A. FIG. 8B illustrates an example of the reference image data RM1 schematically overlapped with the image data IM1. In the example in FIG. 8B, the reference image data RM1 includes a part of the nozzle 31A including a tip end of the nozzle 31A. Vertical and lateral sizes of the reference image data RM1 is smaller than those of the image data IM1. The storage part 94 stores the reference image data RM1, for example. The controller 90 specifies a region in the image data IM1 having a highest degree of similarity to the reference image data RM1 as the position of the nozzle 31A by a template matching, for example.

Then, the controller 90 determines whether or not a difference between this position of the nozzle 31A and the position of the nozzle 31A in the image data IM1 generated in previous Step S12 is equal to or larger than a predetermined difference threshold value. The controller 90 determines that the nozzle 31A is moved when the difference is equal to or larger than the difference threshold value, and determines that the nozzle 31A remains still when the difference is smaller than the difference threshold value. Then, the controller 90 may determine that the nozzle 31A starts to be moved when the nozzle 31A is in a moving state in the image data IM1 subsequent to the image data IM1 in which the nozzle 31A is in a stationary state.

Described next is an example of a method of determining discharge start of the coating solution. When the coating solution is discharged from the nozzle 31A, the coating solution from the nozzle 31A lands the main surface of the substrate W. Thus, fluctuation (that is to say, wave pattern) occurs in the liquid film of the coating solution on the main surface of the substrate W immediately below the nozzle 31A (refer to FIG. 8B). This fluctuation of the liquid film gets largest when a lower end of the coating solution having a liquid columnar shape discharged from the nozzle 31A collides with the liquid film of the substrate W. Subsequently, the fluctuation is relatively small in a state where the coating solution having the liquid columnar shape discharged from the nozzle 31A continuously lands the liquid film of the substrate W.

Thus, the controller 90 may detect change of the fluctuation of the liquid film in a landing position where the coating solution lands the liquid film as change of a discharge state of the coating solution (herein, discharge start) based on the image data IM1. Specifically, the controller 90 may determine magnitude of the fluctuation of the liquid film based on pixel values of a determination region R1 including the landing position of the coating solution. A position and magnitude of the determination region R1 in the image data IM1 is previously set and stored in the storage part 94, for example. When the fluctuation of the liquid film in the landing position increases, diffusion (for example, standard deviation) of the pixel values of the determination region R1 increases. Thus, it is applicable that the controller 90 determines whether or not the diffusion (for example, standard deviation) of the pixel values of the determination region R1 is equal to or larger than a predetermined first diffusion threshold value, and determines that the fluctuation of the liquid film is large when the diffusion is equal to or larger than the first diffusion threshold value. In contrast, the controller 90 may determine that the fluctuation of the liquid film is small when the diffusion is smaller than the first diffusion threshold value.

Then, the controller 90 may determine that the nozzle 31A starts discharging the coating solution when the fluctuation of the liquid film is large in the determination region R1 of the image data IM1 subsequent to the image data IM1 having a small fluctuation of the liquid film in the determination region R1. The controller 90 may determine the magnitude of the fluctuation of the liquid film in the landing position based on the image data IM1 using a learned model which has been mechanically learned. For example, deep learning can be applied to the mechanical learning. This point is also applied to the fluctuation of the liquid film described hereinafter.

As described above, in executing the first process of the coating processing, the controller 90 performs the determination processing of the movement and the determination processing of starting discharging the coating solution based on the image data IM1. The controller 90 executes Step S12 again when the controller 90 does not detect any of the movement and discharge start. In the meanwhile, when the controller 90 detects at least one of the movement or discharge start of the nozzle 31, the controller 90 executes Step S14 described hereinafter.

In Step S14 (calculation step), the controller 90 obtains a time difference between an output time of the control signal and an occurrence time of the event change based on a synchronized time. Herein, since Step S11 is already executed, the time measured by the controller 90 and the camera 5 is synchronized. Then, the controller 90 has a function of measuring a time, thus grasps an output time of the control signal. The controller 90 detects the event change based on the image data IM1 as described above, thus calculates the occurrence time of the event change based on the imaging time of the image data IM1.

For example, when the controller 90 detects start of movement of the nozzle 31A in Step S13, the controller 90 calculates the movement time based on the imaging time of the image data IM1 at a time when the nozzle 31A makes transition from the stationary state to the movement state. As a specific example, the controller 90 may calculate an average time of the imaging times of temporarily-continuous two pieces of image data IM1 at the time when the nozzle 31A makes the transition from the stationary state to the movement state as the movement time. This point can also be applied to calculation of an occurrence time of the other event change. Then, the controller 90 calculates a delay time from the output time of the movement instruction to the movement time. The controller 90 may store delay time data indicating the delay time of the nozzle movement driver 37 in the storage part 94.

The controller 90 may display the delay time on a display of the user interface 95 in response to an input to the user interface 95 by a user. Accordingly, the user can recognize the delay time of the nozzle movement driver 37. This operation is also applied to a delay time of the other driver.

In the example described above, the controller 90 detects start of movement of the nozzle 31A as the event change, but may detect that the nozzle 31A reaches the center position (that is to say, finish of movement). For example, the controller 90 may determine that the nozzle 31A finishes movement when the nozzle 31A is in the stationary state in the image data IM1 subsequent to the image data IM1 in which the nozzle 31A is in the movement state. Then, the controller 90 calculates a movement finish time of the nozzle 31A based on the imaging time of the image data IM1 at the time when the nozzle 31A makes the transition from the movement state to the stationary state, and calculates a delay time from the output time of the movement instruction to the movement finish time. Alternatively, the controller 90 may calculate both the delay time from the output time of the movement instruction to the movement start time and the delay time from the output time of the movement instruction to the movement finish time.

When the controller 90 detects discharge start of the coating solution in Step S13, the controller 90 obtains the discharge start time based on the imaging time of the image data IM1 at the time when the nozzle 31A starts discharging the coating solution. Then, the controller 90 calculates a delay time from the output time of the open instruction to the discharge start time.

Next, the controller 90 determines whether or not the delay time obtained in Step S14 is within a predetermined reference range (Step S15: defect/non-defect determination step). The reference range is previously set in accordance with a type of the delay time. Thus, the reference range for each delay time can be different from a reference range for the other delay time. The reference range indicates a normal range for the corresponding delay time.

When the delay time is within the reference range, the controller 90 determines whether or not to finish the monitoring process (Step S16). For example, the controller 90 may determine that the monitoring process is finished when the substrate process is finished. When the monitoring process is not finished, the processing unit 1 executes Step S12 again.

In the meanwhile, when the delay time is out of the reference range, the controller 90 may perform error processing (Step S17). For example, the controller 90 may make the user interface 95 not shown in the diagrams make a notification of an error as the error processing. For example, when the user interface 95 includes a display, the controller 90 may display the error on the display. Alternatively, when the user interface 95 includes a sound output part such as a speaker, the controller 90 may make the sound output part make a notification of an error. Contents of the error may include information indicating a type of a driver as a target of the error and a delay time. The controller 90 may interrupt the substrate processing as the error processing.

Steps S12 to S15 described above are repetitively executed as the progress of the substrate processing; thus, the image data IM1 can include the change of the state in the chamber 10. For example, when the processing proceeds from the state illustrated in FIG. 8B, as illustrated in FIG. 9A, the camera 5 generates the image data IM1 in which the nozzle 31A reaches the center position and the coating solution is discharged from the nozzle 31A toward the center part of the substrate W.

When the processing further proceeds and the second process of the coating processing is executed, the image data IM1 illustrated in FIG. 9B is generated in Step S12, for example. In this second process, the controller 90 outputs the speed change instruction to the substrate holding part 2 as described above. The substrate holding part 2 changes the rotational speed of the substrate W from the first speed value to the second speed value in response to the speed change instruction. Thus, in executing the second process, the controller 90 determines whether or not the rotational speed of the substrate W is changed as the determination processing of the event change based on the image data IM1 (Step S13).

FIG. 9B illustrates the image data IM1 in which the rotational speed of the substrate W is in the middle of being changed. As illustrated in FIG. 9B, when the rotational speed of the substrate W is changed, change occurs in the fluctuation of the liquid film of the coating solution on the main surface of the substrate W. This fluctuation gets larger in an outer side of the landing position of the coating solution in the radial direction. Thus, the controller 90 may determine magnitude of the fluctuation of the liquid film of the substrate W at a position on the outer side of the landing position in the radial direction based on the image data IM1. For example, the controller 90 may determine magnitude of the fluctuation of the liquid film based on the pixel values of the determination region R2 on the outer side of the landing position of the coating solution in the radial direction. A position and magnitude of the determination region R2 of the image data IM1 is previously set so that the fluctuation of the liquid film in the landing position is not included, for example. It is applicable that the controller 90 determines whether or not the diffusion of the pixel values of the determination region R2 is equal to or larger than a predetermined second diffusion threshold value, and determines that the fluctuation of the liquid film is large when the diffusion is equal to or larger than the second diffusion threshold value. In contrast, the controller 90 may determine that the fluctuation of the liquid film is small when the diffusion in the determination region R2 is equal to or smaller than the second diffusion threshold value.

Then, the controller 90 may determine that the rotational speed of the substrate W starts to be changed when the fluctuation of the liquid film is large in the determination region R2 of the image data IM1 subsequent to the image data IM1 having a small fluctuation of the liquid film in the determination region R2, for example.

As described above, in executing the second process of the coating processing, the controller 90 performs the determination processing of the change of the rotational speed based on the image data IM1. The controller 90 executes Step S14 when detecting the change of the rotational speed of the substrate W.

In Step S14, the controller 90 calculates a time from an output time of the speed change instruction to a first speed change time at which the rotational speed of the substrate W is changed. For example, the controller 90 calculates the first speed change time based on the imaging time of the image data IM1 at a time when the rotational speed of the substrate W starts to be changed. The first speed change time in this time corresponds to a change start time at which the rotational speed of the substrate W starts to be changed. Then, the controller 90 calculates a delay time from the output time of the speed change instruction to the first speed change time.

Next, the controller 90 determines whether or not the delay time of the rotation driver 23 is within the reference range of the rotation driver 23 (Step S15), and performs the error processing (Step S16) when the delay time is out of the reference range.

In the example described above, the controller 90 detects start of change of the rotational speed of the substrate W as the event change. However, the controller 90 may detect that the rotational speed of the substrate W reaches the second speed value (that is to say, finish of change of the rotational speed). For example, it is applicable that the controller 90 determines that change of the rotational speed of the substrate W is finished when the fluctuation of the liquid film is small in the determination region R2 in the image data IM1 subsequent to the image data IM1 having a large fluctuation of the liquid film in the determination region R2, and calculates the first speed change time based on imaging times of these pieces of image data IM1. The first speed change time in this time corresponds to a change finish time at which change of the rotational speed of the substrate W is finished. In this case, the controller 90 calculates a delay time from the output time of the speed change instruction to the change finish time as the delay time. The controller 90 may calculate both the delay time from the output time of the movement instruction to the change start time and the delay time from the output time of the movement instruction to the change finish time. This point is also applied to the second speed change time described hereinafter.

When the processing further proceeds, the third process of the coating processing is executed. In this third process, as described above, the controller 90 outputs the close instruction to the supply valve 33A while outputting the speed change instruction to the substrate holding part 2. The substrate holding part 2 changes the rotational speed of the substrate W from the second speed value to the third speed value in response to the speed change instruction, and the supply valve 33A closes the supply pipe 32A in response to the close instruction.

Thus, in executing the third process, the controller 90 determines whether or not the rotational speed of the substrate W is changed and discharge of the coating solution is stopped as the determination processing of the event change based on the image data IM1 (Step S13). FIG. 10 illustrates the image data IM1 of the image taken when discharge of the coating solution is stopped while the rotational speed of the substrate W is changed. As illustrated in FIG. 10, when the rotational speed of the substrate W is changed, the fluctuation gets large in the liquid film of the coating solution on the main surface of the substrate W. This fluctuation may occur in the outer side of the landing position of the coating solution in the radial direction. When discharge of the coating solution is stopped, the coating solution is divided in a midway portion between the nozzle 31A and the substrate W, and the coating solution on a lower side drops on a side of the substrate W by gravity. Accordingly, the relatively large fluctuation occurs in the coating solution on the main surface of the substrate W in the landing position.

Thus, the controller 90 may determine discharge stop of the coating solution based on the fluctuation of the liquid film in the landing position. It is applicable that the controller 90 determines whether or not the diffusion of a determination region R11 is equal to or larger than a predetermined third diffusion threshold value. The controller 90 determines that the fluctuation of the liquid film is large when the diffusion is equal to or larger than the third diffusion threshold value, and determines that the fluctuation of the liquid film is small when the diffusion is smaller than the third diffusion threshold value. The determination region R11 includes the landing position of the coating solution from the nozzle 31A located in the center position, is a region separated from the determination region R2, and is previously set, for example. The third diffusion threshold value may be the same as or different from the first diffusion threshold value. Then, the controller 90 may determine that discharge of the coating solution is stopped when the fluctuation of the liquid film is large in the determination region R11 of the image data IM1 subsequent to the image data IM1 having a small fluctuation of the liquid film in the determination region R11.

The controller 90 may determine presence or absence of the rotational speed of the substrate W based on the fluctuation of the liquid film in the position on the outer side of the landing position in the radial direction. Specifically, it is applicable that the controller 90 determines that the fluctuation of the liquid film is large when the diffusion of the determination region R2 is equal to or larger than a fourth diffusion threshold value, and determines that the fluctuation of the liquid film is small when the diffusion thereof is smaller than the fourth diffusion threshold value. The fourth diffusion threshold value may be the same as or different from the second diffusion threshold value. Then, the controller 90 detects change of the rotational speed of the substrate W in the manner similar to the determination in the second process.

As described above, in executing the third process of the coating processing, the controller 90 performs the determination processing of the change of the rotational speed and the determination processing of discharge stop of the coating solution based on the image data IM1. The controller 90 executes Step S14 when detecting at least one of the rotational speed change and the discharge stop.

When change of the rotational speed of the substrate W is detected, the controller 90 firstly calculates the second speed change time based on the imaging time of the image data IM1 at a time when the rotational speed of the substrate W is changed in Step S14. Then, the controller 90 calculates a delay time from the output time of the speed change instruction to the second speed change time.

When discharge stop of the liquid solution is detected, the controller 90 firstly calculates the discharge stop time based on the imaging time of the image data IM1 at a time when discharge of the coating solution is stopped in Step S14. Then, the controller 90 calculates a delay time from the output time of the close instruction to the discharge stop time.

Next, the controller 90 determines whether or not the delay time calculated in Step S14 is within the reference range (Step S15), and performs the error processing (Step S17) when the delay time is out of the reference range.

As described above, the controller 90 obtains the output time of the control signal outputted to the driver based on the control clock, and obtains the occurrence time of the event change in the chamber 10 based on the imaging time measured by the camera clock (Step S11 to Step S14). In the present embodiment, the controller 90 synchronizes the current time measured by the control clock and the current time measured by the camera clock by Step S11 (synchronizing step). Thus, the controller 90 can calculate a time difference (herein, the delay time) between the output time of the control signal and the occurrence time of the event change on subsequently the same time axis, and can calculate the delay time with higher accuracy. For example, the delay time for the nozzle movement driver 37, the delay time for the rotation driver 23, and the delay time for change of the discharge state can be obtained with high accuracy.

In the above example, the controller 90 stores the delay time data indicating each delay time in the storage part 94. Then, the controller 90 displays the delay time on the display of the user interface 95 in response to a user input, for example. Accordingly, the user can recognize each delay time of the processing unit 1, and can estimate degradation of each driver, for example. The user may update a required time for each process in the recipe information D1 based on the recognized delay time so that the occurrence time of the event change becomes a more desirable time. For example, when the delay time of the driver is larger than an upper limit of the reference range, the user may update the recipe information D1 so that the output time of the control signal outputted to the driver is outputted at an earlier timing. Such an update can be performed by the upper input to the user interface 95.

In the above example, the controller 90 determines whether or not each delay time is within the reference range (Step S15). Thus, the processing unit 1 can automatically determine whether the delay time is appropriate. When the delay time is out of the reference range, the controller 90 may update the output time (that is to say, the required time of the process) of the control signal in the recipe information D1 based on a deviation amount of the calculated delay time from the reference range so that the occurrence time of the event change becomes a more desirable time.

In the above example, the monitoring processing is performed in the whole period of the substrate processing, but may be performed in at least a part of the period. At least the part of the period is a period including the occurrence time of the event change as a calculation target. For example, when the change time of the discharge state is calculated, at least the part of the period is a period including the change time at which the discharge state of the coating solution is changed.

In the above example, the controller 90 detects change of the fluctuation of the liquid film in the landing position of the coating solution as change of the discharge state of the coating solution (herein, discharge start or discharge stop) based on the image data IM1. According to such a configuration, the controller 90 can detect change of the discharge state with high accuracy.

In the above example, the controller 90 detects change of the fluctuation of the liquid film in the position on the outer side of the landing position of the coating solution in the radial direction as change of the rotational speed of the substrate W based on the image data IM1. According to such a configuration, the controller 90 can detect change of the rotational speed based on the image data IM1.

### <Guard Lifting Driver>

In the above example, the controller 90 outputs the control signal to the guard lifting driver 8, and the guard lifting driver 8 lifts up and down the guard 7 in response to the control signal. Thus, the controller 90 may calculate the delay time from the output time of the control signal outputted to the guard lifting driver 8 to the lifting time of the guard 7. For example, the controller 90 detects positional change of the guard 7 based on the image data IM1 (Step S13). As a specific example, the controller 90 may detect the positional change of the guard 7 based on temporal change of pixel values of a determination region R3 (also refer to FIG. 8A) of the image data IM1. The determination region R3 is a region including at least a part of an upper end peripheral part of the guard 7, and can be previously set.

For example, it is applicable that the controller 90 determines that the guard 7 is lifted up and down when a degree of similarity of the determination regions R3 of the temporality-continuous two piece of image data IM1 is smaller than a predetermined similarity threshold value, and determines that the guard 7 remains still when the degree of similarity thereof is equal to or larger than the predetermined similarity threshold value. The degree of similarity is not particularly limited, but may be a known degree of similarity such as a sum of squared difference of pixel values, a sum of absolute difference of pixel values, a normalizing mutual correlation, and a zero average normalizing mutual correlation, for example.

Then, the controller 90 calculates the lifting time of the guard 7 based on the imaging time of the image data IM1, and calculates the delay time from the output time of the control signal to the lifting time (Step S14). Specifically, the controller 90 may calculate a lifting start time based on the imaging time of the image data IM1 at a time when the guard 7 makes a transition from the stationary state to the lifting state. In this case, the controller 90 calculates a delay time from the output time of the control signal to the lifting start time. Alternatively, the controller 90 may calculate a lifting finish time based on the imaging time of the image data IM1 at a time when the guard 7 makes a transition from the lifting state to the stationary state. In this case, the controller 90 calculates a delay time from the output time of the control signal to the lifting finish time. The controller 90 may calculate both the delay time from the output time to the lifting start time and the delay time from the output time to the lifting finish time.

### <Time Difference of Occurrence Times of Different Event Changes>

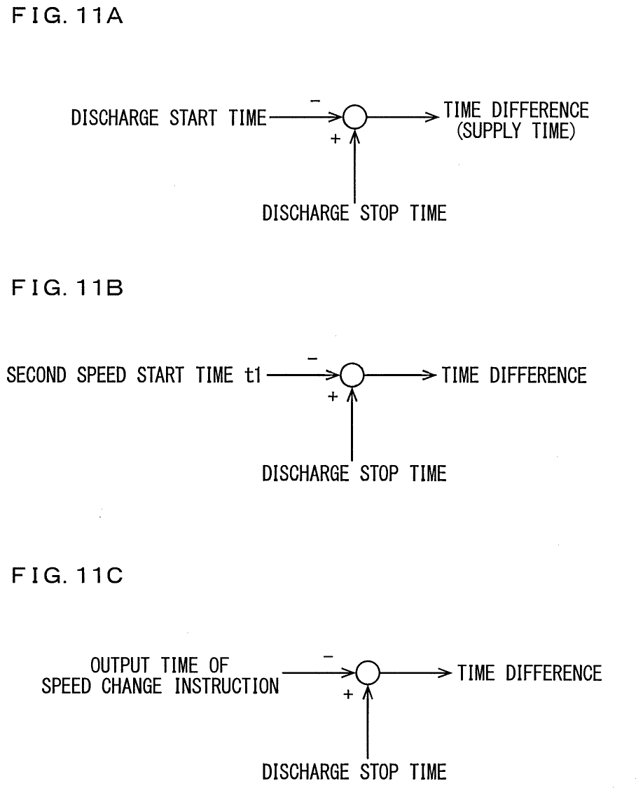

The controller 90 may calculate a time difference of occurrence times of different event changes obtained based on the image data IM1. FIGS. 11A, 11B, and 11C are diagram for explaining the calculation of the time difference.

### <Supply Time of Coating Solution (=Time Difference Between Discharge Start Time and Discharge Stop Time)>

As illustrated in FIG. 11A, the controller 90 may calculate a supply time of supplying the coating solution to the main surface of the substrate W based on the discharge start time and a discharge stop time t2 (also refer to FIG. 6) obtained based on the image data IM1. More specifically, the controller 90 subtracts the discharge start time from the discharge stop time t2 to calculate the supply time. The controller 90 may store supply time data indicating the supply time in the storage part 94. The controller 90 may display the supply time on a display of the user interface 95 in response to an input to the user interface 95 by a user, for example. Accordingly, the user can recognize the supply time. Moreover, the user can recognize occurrence of a defect such as shortage or excess of the supply time. Furthermore, as described above, since the user can also recognize the delay time for the discharge start and the delay time for the discharge stop, the user can also determine whether the defect of the supply time is caused by the discharge start or discharge stop.

The controller 90 may determine whether or not the supply time is within a predetermined supply reference range. When the supply time is within the supply reference range, appropriate coating processing is performed; thus, the controller 90 continues the processing. In the meanwhile, when the supply time is out of the supply reference range, the controller 90 may perform error processing, for example. Accordingly, the user can recognize that error has occurred in the supply time, and can rapidly look for a cause of the defect of the supply time as described above.

### <Time Difference Between Discharge Stop of Coating Solution and Rotational Speed Change in Third Process>

In the above example, in the third process of the coating processing, discharge of the coating solution is stopped during change of the rotational speed of the substrate W (also refer to FIG. 5 and FIG. 6). Thus, a time difference Δt between the second speed change time (for example, the change start time t1) and the discharge stop time t2 has relatively large influence on the film thickness of the coating solution. Thus, as illustrated in FIG. 11B, the controller 90 may calculate the time difference Δt based on the change start time t1 and the discharge stop time t2 obtained based on the image data IM1. Specifically, the controller 90 subtracts the change start time t1 from the discharge stop time t2 to calculate the time difference Δt. The controller 90 may store time difference data indicating the time difference Δt in the storage part 94. The controller 90 may display the time difference Δt on a display of the user interface 95 in response to an input to the user interface 95 by a user, for example. Accordingly, the user can recognize occurrence of a defect such as shortage or excess of the time difference Δt. Furthermore, as described above, the user can also recognize the delay time for change of the rotational speed and the delay time for the discharge stop. Accordingly, the user can also determine whether the defect of the time difference Δt is caused by the rotation driver 23 or the supply valve 33A.

The controller 90 may determine whether or not the time difference Δt is within a predetermined time difference reference range. When the time difference Δt is within the time difference reference range, appropriate coating processing is performed; thus, the controller 90 continues the processing. In the meanwhile, when the time difference Δt is out of the time difference reference range, the controller 90 may perform error processing, for example. Accordingly, the user can recognize that the defect has occurred in the time difference Δt, and can look for a cause of the defect of the time difference Δt as described above.

In the meanwhile, in the above example, the controller 90 obtains the second speed change time (for example, the change start time t1) based on the fluctuation of the liquid film on the main surface of the substrate W in the image data IM1. However, detection accuracy of change of the rotational speed of the substrate W in accordance with the fluctuation of the liquid film is not necessarily high in some cases. The reason is that, for example, the fluctuation of the liquid film in the position on the outer side of the landing position can also be changed by change of a flow amount of the coating solution. Thus, the detection accuracy can be reduced in a case where change of the discharge state and change of the rotational speed of the substrate W occurs in parallel as with the third process of the coating processing. In contrast, since the landing position is located near the center of the substrate W, the fluctuation of the liquid film in the landing position does not depend on change of the rotational speed of the substrate W so much.

Thus, the controller 90 may determine the second speed change time (for example, the change start time t1) based on the output time of outputting the speed change instruction to the substrate holding part 2. Specifically, as illustrated in FIG. 11C, the controller 90 determines the output time of the speed change instruction in the third process as the second speed change time. Then, the controller 90 may subtract the output time of the speed change instruction from the discharge stop time t2 to calculate the time difference Δt. Accordingly, the controller 90 can calculate the time difference Δt with high accuracy and more simple processing.

Herein, a displacement driver is introduced for a more general description. The displacement driver is the nozzle movement driver 37 or the rotation driver 23, for example, and is a driver displacing a displacement target (the nozzle 31 or the substrate W) in the chamber 10. Herein, the controller 90 calculates a time difference between a start time of positional change of the displacement target and a change time of the discharge state of the processing solution. For example, the controller 90 calculates a time difference between the movement start time of the nozzle 31 and the discharge start time of the processing solution. In this case, the controller 90 applies the output time of the control signal (for example, the movement instruction) to the displacement driver (for example, the nozzle movement driver 37) as the start time of the positional change. That is to say, the controller 90 calculates a time difference between the output time of outputting the control signal to the displacement driver and the change time of the discharge state of the coating solution calculated based on the image data IM1.

According to such a configuration, the output time of the control signal is applied to the start time by the displacement driver having high responsibility; thus, the controller 90 can calculate the time difference more simply.

### <Temporal Degradation of Driver>

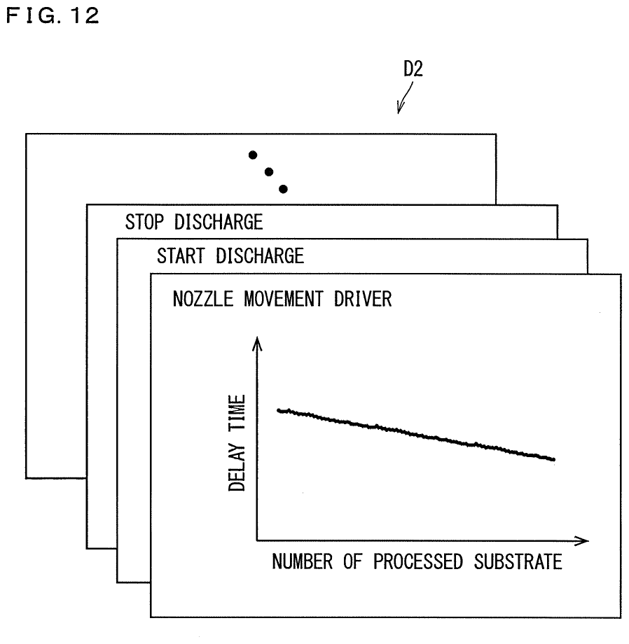

The substrate W is sequentially transported into the processing unit 1. The controller 90 calculates the time difference (including the delay time) described above for each processing of the substrate W, thus generates temporal data D2 indicating temporal change of the time difference. FIG. 12 is a diagram schematically illustrating an example of the temporal data D2. For example, it is applicable that when the controller 90 calculates the delay time of each driver, the controller 90 adds the delay time to the temporal data D2 corresponding to the driver to update the temporal data D2, and stores the updated temporal data D2 in the storage part 94.

The controller 90 may display the temporal data D2 on a display of the user interface 95 in response to an input to the user interface 95 by a user, for example. Accordingly, the user can confirm the temporal change of the time difference based on the temporal data.

### <Variation Between Devices>

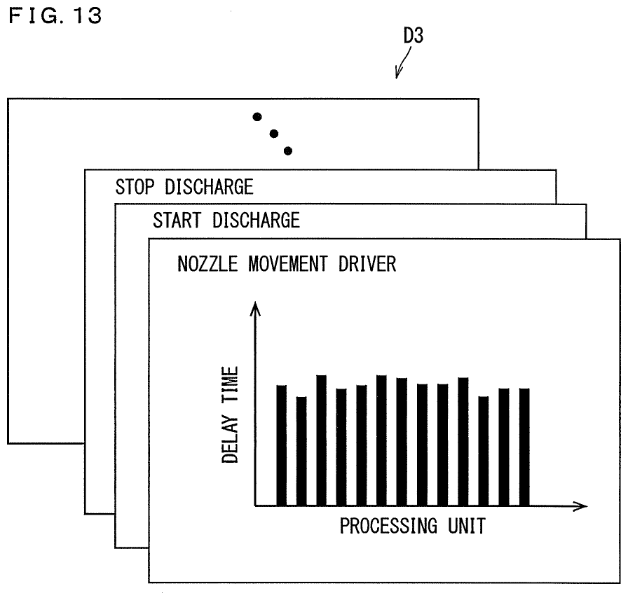

In the above example, the substrate processing device 100 includes the plurality of processing units 1. Each processing unit 1 calculates the time difference (including the delay time) described above in the processing of the substrate W. Thus, the controller 90 generates inter-device data D3 indicating variation between the plurality of processing units 1 in each time difference. FIG. 13 is a diagram schematically illustrating an example of the inter-device data D3. For example, it is applicable that when the controller 90 calculates the delay time of each driver in each processing unit 1, the controller 90 adds the delay time to the inter-device data D3 corresponding to the driver to update the inter-device data D3, and stores the updated inter-device data D3 in the storage part 94.

The controller 90 may display the inter-device data D3 on a display of the user interface 95 in response to an input to the user interface 95 by a user, for example. Accordingly, the user can recognize the variation of the time difference between the plurality of processing units 1.

The controller 90 may previously identify the processing unit 1 most appropriate for the processing in the plurality of processing units by a test, for example, and set each time difference of the identified processing unit 1 to the reference time. The storage part 94 previously stores reference time data indicating the reference time, for example. The controller 90 may determine whether or not a difference between the time difference of each processing unit 1 calculated in Step S14 and the reference time is equal to or larger than a predetermined threshold value. When the difference is equal to or larger than the threshold value, the controller 90 may display error on a display of the user interface 95. The error can include information indicating the processing unit 1 as a target of the error and information indicating a type of the time difference.

### <Synchronizing Processing>

In the above example, the controller 90 outputs the reset signal to the camera 5 to perform the synchronizing processing. However, the configuration is not necessarily limited thereto. For example, the displacement driver controlling a position of a displacement target in the chamber 10 has high responsibility. The displacement driver includes the nozzle movement driver 37, the rotation driver 23, and the guard lifting driver 8, for example. When the controller 90 outputs the control signal to the displacement driver, the position of the displacement target starts to be changed at a time near the output time of the control signal. When the displacement driver has high responsibility, the displacement start time at which the position of the displacement target starts to be changed can be considered to substantially coincide with the output time. The displacement start time corresponds to the movement start time when the displacement target is the nozzle 31.

Thus, the controller 90 may perform the synchronizing processing as described hereinafter. Firstly, the controller 90 detects start of the positional change of the displacement target based on the image data IM1. The detection is performed based on the temporal change of the pixel values of the image data IM1 as described above. Then, the controller 90 obtains the displacement start time at which the displacement targets starts to be changed based on the imaging time of the image data IM1. This displacement start time is obtained based on the imaging time of the image data IM1, thus is a time based on the camera clock. When the displacement driver has high responsibility, a deviation amount between the output time and the displacement start time mainly corresponds to a difference between the time axis of the controller 90 and the time axis of the camera 5. Thus, the controller 90 performs the synchronizing processing based on the output time of the control signal and the displacement start time. Specifically, the controller 90 corrects at least one of a measurement time by the controller 90 and a measurement time by the camera 5 using the deviation amount to reduce a difference between a current time measured by the controller 90 and a current time measured by the camera 5.

According to such a configuration, the controller 90 needs not output a reset signal to the camera 5, and the camera controller 51 needs not have a function corresponding to the reset signal. Thus, the function of the camera controller 51 can be simplified.

### <Second Example of Substrate Processing>

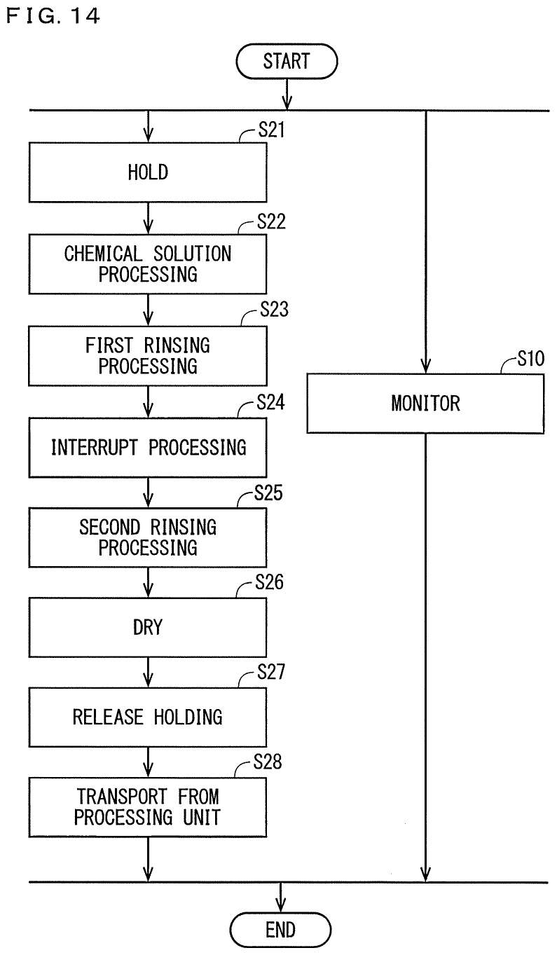

FIG. 14 is a flow chart illustrating a second example of an operation of the processing unit 1. In FIG. 14, the processing unit 1 executes Step S21 to Step S28 to perform the substrate processing (corresponding to the processing step) on the substrate W. Herein, the discharge part 3 of the processing unit 1 includes three nozzles 31 (not shown). More specifically, the processing unit 1 includes the nozzle 31 for a chemical solution (for example, hydrofluoric acid), the nozzle 31 for a first rinse solution (for example, pure water), and the nozzle 31 for a second rinse solution (for example, isopropyl alcohol). Each nozzle 31 is connected to a downstream end of each supply pipe 32, and up upstream end of the supply pipe 32 is connected to the processing solution supply source supplying the corresponding processing solution. The substrate processing in FIG. 14 is also achieved when the controller 90 controls each configuration of the substrate processing device 100 based on the recipe information D1.

Firstly, the second transport part 122 transports the substrate W to the processing unit 1, and the substrate holding part 2 holds the substrate W (Step S21). Next, the processing unit 1 performs chemical solution processing (Step S22). Specifically, the substrate holding part 2 starts rotating the substrate W, the guard lifting driver 8 lifts up the guard 7 to the guard processing position, and the nozzle movement driver 37 moves the nozzle 31 to the nozzle processing position. Next, the discharge part 3 discharges the chemical solution from the nozzle 31 for the chemical solution toward the main surface of the substrate W. Then, the discharge part 3 finishes discharging the chemical solution in response to an elapse of a predetermined chemical solution time.

Next, the processing unit 1 performs first rinsing processing (Step S23). Specifically, the discharge part 3 discharges the first rinse solution from the nozzle 31 for the first rinse solution toward the main surface of the substrate W. Then, the discharge part 3 finishes discharging the first rinse solution in response to an elapse of a predetermined first rinsing time.

Next, the processing unit 1 performs interrupt processing (Step S24). Specifically, close instruction is maintained for all of the supply valves 33 over a predetermined interrupt time (for example, 0.1 seconds). That is to say, after the controller 90 outputs close instruction to the supply valve 33 for the first rinse solution, the controller 90 does not output open instruction to the other supply valve 33 over the interrupt time.

Next, the processing unit 1 performs second rinsing processing (Step S25). Specifically, the discharge part 3 discharges the second rinse solution from the nozzle 31 for the second rinse solution toward the main surface of the substrate W. That is to say, the controller 90 outputs open instruction to the supply valve 33 for the second rinse solution in response to an elapse of an interrupt time from an output time of close instruction to the supply valve 33 for the first rinse solution. Then, the controller 90 outputs close instruction to the supply valve 33 for the second rinse solution in response to an elapse of a second rinsing time from an output time of the open instruction. The nozzle movement driver 37 moves the nozzle 31 to the nozzle standby position.

Next, the processing unit 1 performs drying processing (Step S26). Specifically, the substrate holding part 2 increases the rotational speed of the substrate W (so-called spin drying). The substrate holding part 2 finishes rotating the substrate W in response to an elapse of a predetermined drying time. Next, the substrate holding part 2 releases holding of the substrate W (Step S27), and the second transport part 122 transports the substrate W from the processing unit 1 (Step S28).

As described above, the processing unit 1 can perform the processing on the substrate W. Furthermore, the interrupt processing is performed for a short period of time between the first rinsing processing and the second rinsing processing. In this interrupt processing, a discharge flow amount of the first rinse solution decreases, but the discharge flow amount does not decrease to zero at a time when the interrupt processing is finished. Thus, the liquid film can be maintained on the main surface of the substrate W until discharge of the second rinse solution is started. That is to say, coverage of the substrate W can be ensured. Furthermore, since the discharge flow amount of the first rinse solution is small when discharge of the second rinse solution is started, a possibility of splash of the solution on the main surface of the substrate W can also be reduced.

However, a discharge stop time of the first rinse solution and a discharge start time of the second rinse solution are important to achieve both suppression of such splash of the solution and coverage. Thus, the controller 90 may calculate these times. Specifically, the controller 90 firstly detects discharge stop of the first rinse solution based on the image data IM1, and calculates a delay time from the output time of outputting close instruction to the supply valve 33 for the first rinse solution to the discharge stop time of the first rinse solution based on a synchronized time. The controller 90 detects discharge start of the second rinse solution based on the image data IM1, and calculates a delay time from the output time of outputting open instruction to the supply valve 33 for the second rinse solution to the discharge start time of the second rinse solution based on a synchronized time. When the controller 90 displays each delay time on the user interface 95, a user can confirm whether or not the discharge stop time of the first rinse solution and the discharge start time of the second rinse solution are appropriate. The controller 90 may determine whether or not each delay time is within the reference range, or may also calculate the time difference between the discharge stop time of the first rinse solution and the discharge start time of the second rinse solution to determine whether or not the time difference is within a predetermined time difference reference range.

Also in the second example of the substrate processing, the controller 90 may calculate the time difference from the output time to the other driver to the occurrence time of the event change.

Although the substrate processing device 100 and the substrate processing method are described in detail above, the above description is in all aspects exemplary, and the present disclosure is not limited thereto. The various types of modification examples described above can be applied in combination unless any contradiction occurs. It is understood that countless modification examples that have not been exemplified can be assumed without departing from the scope of the present disclosure.

The present disclosure includes the following aspects.

A first aspect is a substrate processing method, including: a processing step of outputting a control signal to at least one driver of at least one processing unit while a controller measures a time and making the processing unit perform processing on at least one substrate transported into a chamber; imaging step of making a camera take an image in the chamber to generate image data in at least a part of a period in the processing step; a synchronizing step of performing synchronizing processing of reducing a difference between a current time measured by the controller and a current time measured by the camera; and a calculation step of detecting an event change in the chamber based on the image data, calculating an occurrence time of the event change based on an imaging time of the image data, and obtaining a time difference between an output time of the control signal and the occurrence time of the event change based on a synchronized time.

A second aspect is the substrate processing method according to the first aspect, wherein in the processing step, the controller outputs movement instruction as the control signal to a nozzle movement driver to make the nozzle movement driver move a nozzle discharging a processing solution toward a main surface of the substrate, and in the calculation step, the controller detects movement of the nozzle based on the image data and obtains a delay time as the time difference from the output time of the movement instruction to a movement time of the nozzle based on a synchronized time.

A third aspect is the substrate processing method according to the first or second aspect, wherein in the processing step, the controller outputs open instruction or close instruction as the control signal to a supply valve provided to a supply pipe connected to a nozzle discharging a processing solution to a main surface of the substrate, and in the calculation processing, the controller detects change of a discharge state of the processing solution from the nozzle based on the image data and obtains a delay time as the time difference from the output time of the control signal to a change time of the discharge state based on a synchronized time.

A fourth aspect is the substrate processing method according to the third aspect, wherein in the processing step, after the controller outputs the open instruction to the supply valve to discharge the processing solution from the nozzle, the controller outputs the close instruction to the supply valve to stop discharging the processing solution from the nozzle, and in the calculation step, the controller detects discharge start of the processing solution from the nozzle corresponding to the open instruction based on the image data, detects discharge stop of the processing solution from the nozzle corresponding to the close instruction based on the image data, and obtains a supply time from a discharge start time to a discharge stop time of the processing solution.

A fifth aspect is the substrate processing method according to the third or fourth aspect, wherein in the calculation step, the controller detects change of fluctuation of the processing solution in a landing position where the processing solution lands on the main surface of the substrate as change of the discharge state of the processing solution based on the image data.

A sixth aspect is the substrate processing method according to any one of the first to fifth aspects, wherein in the processing step, the controller outputs speed change instruction as the control signal to a rotation driver rotating the substrate while causing a nozzle to discharge a processing solution toward a main surface of the substrate, and in the calculation step, the controller detects change of fluctuation of the processing solution on the main surface of the substrate in a position on an outer side of the landing position of the processing solution in a radial direction as change of a rotational speed of the substrate based on the image data.

A seventh aspect is the substrate processing method according to any one of the first to sixth aspects, wherein in the processing step, the controller outputs the control signal to a displacement driver displacing a position of a displacement target in the chamber and outputs open instruction or close instruction as the control signal to a supply valve provided to a supply pipe connected to a nozzle discharging a processing solution to a main surface of the substrate, and in the calculation step, the controller detects change of a discharge state of the processing solution from the nozzle based on the image data and obtains the time difference between the output time of the control signal to the displacement driver and a change time of the discharge state of the processing solution based on a synchronized time.

An eighth aspect is the substrate processing method according to the seventh aspect, wherein in the processing step, the controller outputs the close instruction to the supply valve and outputs speed change instruction as the control signal to a rotation driver as the displacement driver rotating the substrate, and in the calculation step, the controller detects discharge stop of the processing solution from the nozzle based on the image data and obtains the time difference between the output time of the speed change instruction and a discharge stop time of the processing solution based on a synchronized time.

A ninth aspect is the substrate processing method according to any one of the first to eight aspects, wherein in the processing method, the controller outputs the control signal to a displacement driver displacing a position of a displacement target in the chamber, and in the synchronizing step, the controller detects start of positional change of the displacement target in the chamber based on the image data, calculates a displacement start time at which a position of the displacement target starts to be changed based on an imaging time of the image data, and performs the synchronizing processing based on an output time of the control signal and the displacement start time.

A tenth aspect is the substrate processing method according to any one of the first to ninth aspects, wherein the processing step, the imaging step, the synchronizing step, and the calculation step are performed on each of the plurality of substrates, and temporal data indicating temporal change of the time difference for the plurality of substrates is generated. An eleventh aspect is the substrate processing method according to any one of the first to tenth aspects, wherein the processing step, the imaging step, the synchronizing step, and the calculation step are performed on each of the plurality of processing units, and inter-device data indicating variation of the time difference between the plurality of processing units is generated.

A twelfth aspect is a substrate processing device including: a chamber; a camera taking an image of an inner side of the chamber and generating image data; a driver for performing processing on a substrate transported into the chamber; and a controller outputting a control signal to the driver so that the driver performs processing on the substrate transported into the chamber, wherein the controller performs synchronizing processing of reducing a difference between a current time measured by the controller and a current time measured by the camera, detects an event change in the chamber based on the image data, calculates an occurrence time of the event change based on an imaging time of the image data, and obtains a time difference between an output time of the control signal and the occurrence time of the event change based on a synchronized time.

According to the first and twelfth aspects, the time difference between the output time of the control signal and the occurrence time of the event change can be obtained with high accuracy.

According to the second aspect, the delay time for the nozzle movement driver can be obtained with high accuracy.

According to the third aspect, the delay time for the discharge state can be obtained with high accuracy.

According to the fourth aspect, the supply time can be obtained.

According to the fifth aspect, change of the discharge state can be detected with high accuracy based on the image data.

According to the sixth aspect, change of the rotational speed can be detected based on the image data.

According to the seventh aspect, since the displacement driver has high responsibility, the displacement start time at which the position of the displacement target starts to be changed substantially coincides with the output time of outputting the control signal to the displacement driver. Thus, the time difference between the discharge start time and the change time of the discharge state can be obtained with high accuracy.

According to the eighth aspect, the time difference between the change start time of the rotational speed of the substrate and the discharge stop time of the processing solution can be obtained more simply with higher accuracy.

According to the ninth aspect, since the reset signal for the camera is unnecessary, a function of the camera can be simplified.

According to the tenth aspect, the temporal change of the driver can be confirmed.

According to the eleventh aspect, variation of the driver between the plurality of processing units can be confirmed.

While the invention has been shown and described in detail, the foregoing description is in all aspects illustrative and not restrictive. It is therefore understood that numerous modifications and variations can be devised without departing from the scope of the invention.

What is claimed is:

1. A substrate processing method, comprising:
a processing step of outputting a control signal to at least one driver of at least one processing unit while a controller measures a time and making the processing unit perform processing on at least one substrate transported into a chamber;
imaging step of making a camera take an image in the chamber to generate image data in at least a part of a period in the processing step;
a synchronizing step of performing synchronizing processing of reducing a difference between a current time measured by the controller and a current time measured by the camera; and
a calculation step of detecting an event change in the chamber based on the image data, calculating an occurrence time of the event change based on an imaging time of the image data, and obtaining a time difference between an output time of the control signal and the occurrence time of the event change based on a synchronized time.

2. The substrate processing method according to claim 1, wherein
in the processing step, the controller outputs movement instruction as the control signal to a nozzle movement driver to make the nozzle movement driver move a nozzle discharging a processing solution toward a main surface of the substrate, and
in the calculation step, the controller detects movement of the nozzle based on the image data and obtains a delay time as the time difference from the output time of the movement instruction to a movement time of the nozzle based on a synchronized time.

3. The substrate processing method according to claim 1, wherein
in the processing step, the controller outputs open instruction or close instruction as the control signal to a supply valve provided to a supply pipe connected to a nozzle discharging a processing solution to a main surface of the substrate, and
in the calculation processing, the controller detects change of a discharge state of the processing solution from the nozzle based on the image data and obtains a delay time as the time difference from the output time of the control signal to a change time of the discharge state based on a synchronized time.

4. The substrate processing method according to claim 3, wherein
in the processing step, after the controller outputs the open instruction to the supply valve to discharge the processing solution from the nozzle, the controller outputs the close instruction to the supply valve to stop discharging the processing solution from the nozzle, and
in the calculation step, the controller detects discharge start of the processing solution from the nozzle corresponding to the open instruction based on the image data, detects discharge stop of the processing solution from the nozzle corresponding to the close instruction based on the image data, and obtains a supply time from a discharge start time to a discharge stop time of the processing solution.

5. The substrate processing method according to claim 3, wherein
in the calculation step, the controller detects change of fluctuation of the processing solution in a landing position where the processing solution lands on the main surface of the substrate as change of the discharge state of the processing solution based on the image data.

6. The substrate processing method according to claim 1, wherein
in the processing step, the controller outputs speed change instruction as the control signal to a rotation driver rotating the substrate while causing a nozzle to discharge a processing solution toward a main surface of the substrate, and
in the calculation step, the controller detects change of fluctuation of the processing solution on the main surface of the substrate in a position on an outer side of the landing position of the processing solution in a radial direction as change of a rotational speed of the substrate based on the image data.

7. The substrate processing method according to claim 1, wherein
in the processing step, the controller outputs the control signal to a displacement driver displacing a position of a displacement target in the chamber and outputs open instruction or close instruction as the control signal to a supply valve provided to a supply pipe connected to a nozzle discharging a processing solution to a main surface of the substrate, and
in the calculation step, the controller detects change of a discharge state of the processing solution from the nozzle based on the image data and obtains the time difference between the output time of the control signal to the displacement driver and a change time of the discharge state of the processing solution based on a synchronized time.

8. The substrate processing method according to claim 7, wherein
in the processing step, the controller outputs the close instruction to the supply valve and outputs speed change instruction as the control signal to a rotation driver as the displacement driver rotating the substrate, and
in the calculation step, the controller detects discharge stop of the processing solution from the nozzle based on the image data and obtains the time difference between the output time of the speed change instruction and a discharge stop time of the processing solution based on a synchronized time.

9. The substrate processing method according to claim 1, wherein
in the processing method, the controller outputs the control signal to a displacement driver displacing a position of a displacement target in the chamber, and
in the synchronizing step, the controller detects start of positional change of the displacement target in the chamber based on the image data, calculates a displacement start time at which a position of the displacement target starts to be changed based on an imaging time of the image data, and performs the synchronizing processing based on an output time of the control signal and the displacement start time.

10. The substrate processing method according to claim 1, wherein
the processing step, the imaging step, the synchronizing step, and the calculation step are performed on each of the plurality of substrates, and
temporal data indicating temporal change of the time difference for the plurality of substrates is generated.

11. The substrate processing method according to claim 1, wherein
the processing step, the imaging step, the synchronizing step, and the calculation step are performed on each of the plurality of processing units, and
inter-device data indicating variation of the time difference between the plurality of processing units is generated.

12. A substrate processing device, comprising:
a chamber;
a camera taking an image of an inner side of the chamber to generate image data;
a driver for performing processing on a substrate transported into the chamber; and
a controller outputting a control signal to the driver so that processing is performed on the substrate transported into the chamber, the controller performing synchronizing processing of reducing a difference between a current time measured by the controller and a current time measured by the camera, detects an event change in the chamber based on the image data, calculates an occurrence time of the event change based on an imaging time of the image data, and obtains a time difference between an output time of the control signal and the occurrence time of the event change based on a synchronized time.
